(19) United States
(12) Patent Application Publication
(10) Pub. No.: US 2012/0154944 A1
(43) Pub. Date: Jun. 21, 2012

(54) COLOR CURABLE COMPOSITION AND METHOD OF PREPARING THE SAME, COLOR FILTER AND METHOD OF PRODUCING THE SAME, AND SOLID-STATE IMAGE PICK-UP DEVICE

(75) Inventor: Shinichi Kanna, Shizuoka (JP)

(73) Assignee: FUJIFILM CORPORATION, Minato-ku, Tokyo (JP)

(21) Appl. No.: 13/393,761

(22) PCT Filed: Aug. 27, 2010
(86) PCT No.: PCT/JP2010/065087

§ 371 Date: Mar. 1, 2012

(30) Foreign Application Priority Data
Sep. 3, 2009 (JP) 2009-203704

(51) Int. Cl. G02B 5/22; G03F 7/004; G03F 7/027; G03F 7/20

(52) U.S. Cl. 359/891; 430/7; 430/270.1; 430/281.1

(57) ABSTRACT

A method of preparing a color curable composition, comprising: preparing a dye solution by dissolving at least a dye in an organic solvent; preparing a pigment dispersion liquid by dispersing at least a pigment using a dispersant; and mixing the dye solution and the pigment dispersion liquid.

### TECHNICAL FIELD

The present invention relates to a color curable composition and a method of preparing the same, a color filter and a method of producing the same, and a solid-state image pick-up device.

### BACKGROUND ART

Pigment dispersion methods are widely known as methods for producing color filters for use in liquid crystal display apparatuses (such as LCDs) and solid-state image pick-up devices (such as CCDs and CMOSs).

Pigment dispersion methods are methods in which a color filter is produced by photolithography using a color curable composition containing a pigment dispersed in a photosensitive composition, which may be selected from various photosensitive compositions. Pigment dispersion methods realize high positional accuracy due to the use of photolithography for patterning, and are suitable for production of large-area high-definition color filters. Production of color filters by pigment dispersion methods includes applying a color curable composition onto a glass substrate using a spin coater, a roll coater, or the like to form a coating film, pattern-wise exposing the coating layer to light and developing the same to form color pixels, and repeating these operations for the respective colors to form a color filter.

A blue curable composition for a color filter that contains a phthalocyanine pigment and that is described in JP-A No. 2001-33616 is known an example of a color curable composition containing a pigment.

Pigments having smaller particle sizes are requested for production of liquid crystal displays and solid-state image pick-up devices that have color filters containing pigments, from the viewpoint of improving contrast and resolution. The reasons therefor include scattering of light by a pigment, and rotation of the polarization axis by a pigment through birefringence and the like. Insufficient fining of the pigment results in scattering and absorption of light by the pigment, which, in turn, results in decreases in light transmittance and contrast, higher tendency towards color unevenness, and a decrease in curing sensitivity at the time of pattern-wise exposure.

Although a further increase in resolution of color filters for solid-state image pick-up devices has been desired in recent years, a further increase in resolution is difficult to achieve by using conventional pigment dispersion methods. Specifically, there are problems associated therewith, such as generation of color unevenness caused by an influence of the presence of coarse pigment particles. Therefore, the pigment dispersion methods have not been suitable for applications in which fine patterns with a pixel size of from 0.9 μm square to 3.0 μm square are required, such as for solid-state image pick-up devices.

In order to deal with the above situation, techniques whereby dyes are used instead of pigments have been proposed. However, dyes are known to generally have inferior light fastness and inferior thermal resistance compared to pigments, and thus the use of dyes has been problematic in terms of color filter properties in some cases. Further, dyes have low solubility in color curable compositions, and the stability thereof over time are low if the dyes are contained in liquid preparations or coating films, as a result of which problems such as precipitation of dyes may arise.

In consideration of these problems, Japanese Patent Application Laid-open (JP-A) No. 2008-292970 describes a color curable composition having favorable storage stability and capable of forming a color filter with high light-fastness, which is achieved by a combined use of a dye containing a dipyrromethene compound and a phthalocyanine dye.

Although a color curable composition containing a dye and a pigment in combination is described in JP-A No. 2009-86375, attention is paid neither to a preparation method of a color curable composition containing a dye and a pigment, nor to liquid properties of the color curable composition.

### SUMMARY OF INVENTION

When a color curable composition is prepared using a pigment and a dye as described above, the dye and the pigment are mixed. The method for mixing the pigment and the dye may be a method of directly mixing a dye powder into a pigment dispersion in which the pigment is dispersed, thereby preparing a color curable composition. However, there has been a problem in that, when the solids concentration in the color curable composition is high or when the mass ratio of the dye to the pigment is high, direct addition of the dye powder into the pigment dispersion liquid results in a change of the dispersion state of the pigment during the course of the dissolution of the dye into the solvent in an agitation dissolution step after the direct addition, thereby leading to deterioration of the dispersibility and dispersion stability of the pigment.

Further, when a dye powder is directly added to a pigment dispersion liquid, there have been problems also in production: for example, dissolution of the dye powder takes a long time in some cases or the dye does not dissolve completely in some cases, and dissolution of the dye powder is hard to confirm.

The present invention has been made in view of the above. An object of the present invention is provision of a method of preparing a color curable composition having excellent dispersibility and excellent dispersion stability and a color curable composition obtainable by the preparation method, a method of producing a color filter having high color purity and reduced color unevenness and a color filter obtainable by the production method, and a solid-state image pick-up device having high resolution.

Specific measures for achieving the object include the following:

<1> A method of preparing a color curable composition, including:

preparing a dye solution by dissolving at least a dye in an organic solvent;

preparing a pigment dispersion liquid by dispersing at least a pigment using a dispersant; and

mixing the dye solution and the pigment dispersion liquid.

<2> A method of preparing a color curable composition as described in <1>, wherein the amount of solids contained in the color curable composition is from 13% by mass to 20% by mass relative to the entire color curable composition.

<3> A method of preparing a color curable composition as described in <1> or <2>, wherein the amount of pigments contained in the color curable composition is from 10% by mass to 60% by mass relative to the amount of solids contained in the color curable composition, and the amount of dyes contained in the color curable composition is from 10% by mass to 60% by mass relative to the amount of solids contained in the color curable composition.

<4> A method of preparing a color curable composition as described in any one of <1> to <3>, wherein the amount of dyes contained in the color curable composition is from 20% by mass to 500% by mass relative to the amount of pigments contained in the color curable composition.

<5> A method of preparing a color curable composition as described in any one of <1> to <4>, wherein the organic solvent contained in the dye solution is at least one selected from the group consisting of cyclohexanone, propyleneglycol monomethyl ether acetate, propyleneglycol monomethyl ether, and ethyl lactate.

<6> A method of preparing a color curable composition as described in any one of <1> to <5>, wherein the pigment includes a phthalocyanine pigment, and the dye is a complex in which a compound represented by the following Formula (I) coordinates to a metal atom or metal compound:

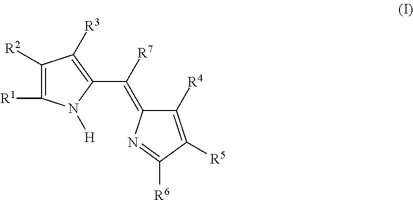

In Formula (I), R¹ to R⁶ each independently represent a hydrogen atom or a substituent, and R⁷ represents a hydrogen atom, a halogen atom, an alkyl group, an aryl group, or a heterocyclic group.

<7> A color curable composition obtainable by the method of preparing a color curable composition described in any one of <1> to <6>.

<8> The color curable composition as described in <7>, further including a polymerizable compound and a polymerization initiator.

<9> A method of producing a color filter, including:

forming a color curable composition layer by applying the color curable composition described in <7> or <8> onto a support; and

forming a color pattern by exposing the color curable composition layer to light through a mask and thereafter developing the color curable composition layer.

<10> A color filter obtainable by the method of producing a color filter described in <9>.

<11> A solid-state image pick-up device including the color filter described in <10>.

In the invention, a pigment dispersion liquid in which a pigment is dispersed with a dispersant is prepared, and, separately, ingredients including a dye powder are dissolved in an organic solvent to form a dye solution. Thereafter, the pigment dispersion liquid and the dye solution are mixed with each other to form a color curable composition. Through these processes, the dispersion state of the pigment is substantially not affected by the addition of the dye, and the dispersion state is improved. It is surmised that the reason therefor is that the dye is uniformly dissolved to a molecular level, the dye molecules adsorb on and protects the surface of the pigment, thereby realizing an improved dispersion state. It is thought that the improved dispersion state provides capability of maintaining the dispersion stability of the pigment, and results in a decrease in a change of the dispersion over time.

Further, according to the invention, since the time required for dissolving the dye powder to form a solution is shortened, a color curable composition can be prepared in a shorter time, and the dissolution of the dye in the organic solvent can be easily confirmed, as a result of which the preparation of a color curable composition is facilitated.

### DESCRIPTION OF EMBODIMENTS

The method of preparing a color curable composition according to the invention includes a process of preparing a dye solution by dissolving at least a dye in an organic solvent, a process of preparing a pigment dispersion liquid by dispersing at least a pigment using a dispersant, and a process of mixing the dye solution and the pigment dispersion liquid.

<Dye Solution and Dye>

First, the process of dissolving at least a dye in an organic solvent to form a dye solution is described.

The dye to be used in the invention is not particularly limited, and known dyes that have been used for color filters can be used. Examples thereof include the dyes described in JP-A No. 64-90403, JP-A No. 64-91102, JP-A No. 1-94301, JP-A No. 6-11614, Japanese Patent No. 2592207, U.S. Pat. No. 4,808,501, U.S. Pat. No. 5,667,920, U.S. Pat. No. 5,059,500, JP-A No. 5-333207, JP-A No. 6-35183, JP-A No. 6-51115, JP-A No. 6-194828, JP-A No. 8-211599, JP-A No. 4-249549, JP-A No. 10-123316, JP-A No. 11-302283, JP-A No. 7-286107, JP-A No. 2001-4823, JP-A No. 8-15522, JP-A No. 8-29771, JP-A No. 8-146215, JP-A No. 11-343437, JP-A No. 8-62416, JP-A No. 2002-14220, JP-A No. 2002-14221, JP-A No. 2002-14222, JP-A No. 2002-14223, JP-A No. 8-302224, JP-A No. 8-73758, JP-A No. 8-179120, and JP-A No. 8-151531.

With regard to preferable chemical structures of dyes, examples of dyes include pyrazole azo dyes, anilino azo dyes, triphenylmethane dyes, anthraquinone dyes, anthrapyridone dyes, benzylidene dyes, oxonol dyes, pyrazolotriazole azo dyes, pyridone azo dyes, cyanine dyes, phenothiazine dyes, pyrrolopyrazole azo methine dyes, xanthene dyes, phthalocyanine dyes, benzopyran dyes, and indigo dyes.

Complex Containing a Compound Represented by Formula (I) and a Metal Atom or Metal Compound

The dye is preferably a complex in which a compound represented by the following Formula (I) coordinates to a metal atom or metal compound (hereinafter referred to as “specific complex” in some cases).

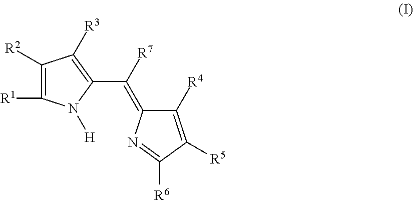

In Formula (I), R¹ to R⁶ each independently represent a hydrogen atom or a substituent. R⁷ represents a hydrogen atom, a halogen atom, an alkyl group, an aryl group, or a heterocyclic group.

Examples of the substituent that any of R¹ to R⁶ in Formula (1) may represent include the following monovalent groups. The monovalent groups described below are hereinafter indicated by a generic term “substituents R” in some cases.

Specifically, examples of a monovalent group that any of R¹ to R⁶ may represent include: a halogen atom (such as a fluorine atom, a chlorine atom, or a bromine atom); an alkyl group (a linear, branched, or cyclic alkyl group having preferably from 1 to 48 carbon atoms, more preferably from 1 to 24 carbon atoms, such as a methyl group, an ethyl group, a propyl group, an isopropyl group, a butyl group, a t-butyl group, a pentyl group, a hexyl group, a heptyl group, an octyl group, a 2-ethylhexyl group, a dodecyl group, a hexadecyl group, a cyclopropyl group, a cyclopentyl group, a cyclohexyl group, a 1-norbornyl group, or a 1-adamantyl group); an alkenyl group (an alkenyl group having preferably from 2 to 28 carbon atoms, more preferably from 2 to 18 carbon atoms, such as a vinyl group, an allyl group, or a 3-butene-1-yl group); an aryl group (an aryl group having preferably from 6 to 48 carbon atoms, more preferably from 6 to 24 carbon atoms, such as a phenyl group or a naphthyl group); a heterocyclic group (a heterocyclic group having preferably from 1 to 32 carbon atoms, more preferably from 1 to 18 carbon atoms, such as a 2-thienyl group, a 4-pyridyl group, a 2-furyl group, a 2-pyrimidinyl group, a 1-pyridyl group, a 2-benzothiazolyl group, a 1-imidazolyl group, a 1-pyrazolyl group, or a benzotriazole-1-yl group); a silyl group (a silyl group having preferably from 3 to 38 carbon atoms, more preferably from 3 to 18 carbon atoms, such as a trimethylsilyl group, a triethylsilyl group, a tributylsilyl group, a t-butyldimethylsilyl group or a t-hexyldimethylsilyl group); a hydroxyl group, a cyano group, a nitro group, an alkoxy group (an alkoxy group having preferably from 1 to 48 carbon atoms, more preferably from 1 to 24 carbon atoms, such as a methoxy group, an ethoxy group, a 1-butoxy group, a 2-butoxy group, an isopropoxy group, a t-butoxy group, a dodecyloxy group, or a cycloalkyloxy group such as a cyclopentyloxy group or a cyclohexyloxy group); an aryloxy group (an aryloxy group having preferably from 6 to 48 carbon atoms, more preferably from 6 to 24 carbon atoms, such as a phenoxy group or a 1-naphthoxy group); a heterocyclic oxy group (a heterocyclic oxy group having preferably from 1 to 32 carbon atoms, more preferably from 1 to 18 carbon atoms, such as a 1-phenyltetrazole-5-oxy group or a 2-tetrahydropyranyloxy group); a silyloxy group (a silyloxy group having preferably from 1 to 32 carbon atoms, more preferably from 1 to 18 carbon atoms, such as a trimethylsilyloxy group, a t-butyldimethylsilyloxy group, or a diphenylmethylsilyloxy group); an acyloxy group (an acyloxy group having preferably from 2 to 48 carbon atoms, more preferably from 2 to 24 carbon atoms, such as an acetoxy group, a pivaloyloxy group, a benzoyloxy group, or a dodecanoyloxy group); an alkoxycarbonyloxy group (an alkoxycarbonyloxy group having preferably from 2 to 48 carbon atoms, more preferably from 2 to 24 carbon atoms, such as an ethoxycarbonyloxy group, a t-butoxycarbonyloxy group, or a cycloalkyloxycarbonyloxy group such as a cyclohexyloxycarbonyloxy group); an aryloxycarbonyloxy group (an aryloxycarbonyloxy group having preferably from 7 to 32 carbon atoms, more preferably from 7 to 24 carbon atoms, such as a phenoxycarbonyloxy group); a carbamoyloxy group (a carbamoyloxy group having preferably from 1 to 48 carbon atoms, more preferably from 1 to 24 carbon atoms, such as a N,N-dimethylcarbamoyloxy group, a N-butylcarbamoyloxy group, a N-phenylcarbamoyloxy group, or a N-ethyl-N-phenylcarbamoyloxy group); a sulfamoyloxy group (a sulfamoyloxy group having preferably from 1 to 32 carbon atoms, more preferably from 1 to 24 carbon atoms, such as a N,N-diethylsulfamoyloxy group or a N-propylsulfamoyloxy group); an alkylsulfonyloxy group (an alkylsulfonyloxy group having preferably from 1 to 38 carbon atoms, more preferably from 1 to 24 carbon atoms, such as a methylsulfonyloxy group, a hexadecylsulfonyloxy group, or a cyclohexylsulfonyloxy group);

an arylsulfonyloxy group (an arylsulfonyloxy group having preferably from 6 to 32 carbon atoms, more preferably from 6 to 24 carbon atoms, such as a phenylsulfonyloxy group); an acyl group (an acyl group having preferably from 1 to 48 carbon atoms, more preferably from 1 to 24 carbon atoms, such as a formyl group, an acetyl group, a pivaloyl group, a benzoyl group, a tetradecanoyl group, or a cyclohexanoyl group); an alkoxycarbonyl group (an alkoxycarbonyl group having preferably from 2 to 48 carbon atoms, more preferably from 2 to 24 carbon atoms, such as a methoxycarbonyl group, an ethoxycarbonyl group, an octadecyloxycarbonyl group, a cyclohexyloxycarbonyl group, or a 2,6-di-tert-butyl-4-methylcyclohexyloxycarbonyl group); an aryloxycarbonyl group (an aryloxycarbonyl group having preferably from 7 to 32 carbon atoms, more preferably from 7 to 24 carbon atoms, such as a phenoxycarbonyl group); a carbamoyl group (a carbamoyl group having preferably from 1 to 48 carbon atoms, more preferably from 1 to 24 carbon atoms, such as a carbamoyl group, N,N-diethylcarbamoyl group, a N-ethyl-N-octylcarbamoyl group, N,N-dibutylcarbamoyl group, a N-propylcarbamoyl group, a N-phenylcarbamoyl group, a N-methyl-N-phenylcarbamoyl group, or a N,N-dicyclohexylcarbamoyl group); an amino group (an amino group having preferably 32 or fewer carbon atoms, more preferably 24 or fewer carbon atoms, such as an amino group, a methylamino group, a N,N-dibutylamino group, a tetradecylamino group, a 2-ethylhexylamino group, or a cyclohexylamino group); an anilino group (an anilino group having preferably from 6 to 32 carbon atoms, more preferably from 6 to 24 carbon atoms, such as an anilino group or a N-methylanilino group); a heterocyclic amino group (a heterocyclic amino group having preferably from 1 to 32 carbon atoms, more preferably from 1 to 18 carbon atoms, such as a 4-pyridylamino group); a carbonamido group (a carbonamido group having preferably from 2 to 48 carbon atoms, more preferably from 2 to 24 carbon atoms, such as an acetamido group, a benzamido group, a tetradecanamido group, a pivaloylamido group, or a cyclohexanamido group); a ureido group (a ureido group having preferably from 1 to 32 carbon atoms, more preferably from 1 to 24 carbon atoms, such as a ureido group, a N,N-dimethylureido group, or a N-phenylureido group); an imido group (an imido group having preferably from 36 or fewer carbon atoms, more preferably 24 or fewer carbon atoms, such as a N-succinimido group or a N-phthalimido group); an alkoxycarbonylamino group (an alkoxycarbonylamino group having preferably from 2 to 48 carbon atoms, more preferably from 2 to 24 carbon atoms, such as a methoxycarbonylamino group, an ethoxycarbonylamino group, a t-butoxycarbonylamino group, an octadecyloxycarbonylamino group, or a cyclohexyloxycarbonylamino group); an aryloxycarbonylamino group (an aryloxycarbonylamino group having preferably from 7 to 32 carbon atoms, more preferably from 7 to 24 carbon atoms, such as a phenoxycarbonylamino group); a sulfonamido group (a sulfonamido group having preferably from 1 to 48 carbon atoms, more preferably from 1 to 24 carbon atoms, such as a methanesulfonamido group, a butanesulfonamido group, a benzenesulfonamido group, a hexadecanesulfonamido group, or a cyclohexanesulfonamido group); a sulfamoylamino group (a sulfamoylamino group having preferably from 1 to 48 carbon atoms, more preferably from 1 to 24 carbon atoms, such as a N,N-dipropylsulfamoylamino group or a N-ethyl-N-dodecylsulfamoylamino group); an azo group (an azo group having preferably from 1 to 32 carbon atoms, more preferably from 1 to 24 carbon atoms, such as a phenylazo group or a 3-pyrazolylazo group);

an alkylthio group (an alkylthio group having preferably from 1 to 48 carbon atoms, more preferably from 1 to 24 carbon atoms, such as a methylthio group, an ethylthio group, an octylthio group, or a cyclohexylthio group); an arylthio group (an arylthio group having preferably from 6 to 48 carbon atoms, more preferably from 6 to 24 carbon atoms, such as a phenylthio group); a heterocyclylthio group (a heterocyclylthio group having preferably from 1 to 32 carbon atoms, more preferably from 1 to 18 carbon atoms, such as a 2-benzothiazolylthio group, a 2-pyridylthio group, or a 1-phenyltetrazolylthio group); an alkylsulfinyl group (an alkylsulfinyl group having preferably from 1 to 32 carbon atoms, more preferably from 1 to 24 carbon atoms, such as a dodecanesulfinyl group); an arylsulfinyl group (an arylsulfinyl group having preferably from 6 to 32 carbon atoms, more preferably from 6 to 24 carbon atoms, such as a phenylsulfinyl group); an alkylsulfonyl group (an alkylsulfonyl group having preferably from 1 to 48 carbon atoms, more preferably from 1 to 24 carbon atoms, such as a methylsulfonyl group, an ethylsulfonyl group, a propylsulfonyl group, a butylsulfonyl group, an isopropylsulfonyl group, a 2-ethylhexylsulfonyl group, a hexadecylsulfonyl group, an octylsulfonyl group, or a cyclohexylsulfonyl group); an arylsulfonyl group (an arylsulfonyl group having preferably from 6 to 48 carbon atoms, more preferably from 6 to 24 carbon atoms, such as a phenylsulfonyl group or a 1-naphthylsulfonyl group); a sulfamoyl group (a sulfamoyl group having preferably 32 or fewer carbon atoms, more preferably 24 or fewer carbon atoms, such as a sulfamoyl group, a N,N-dipropylsulfamoyl group, a N-ethyl-N-dodecylsulfamoyl group, a N-ethyl-N-phenylsulfamoyl group, or a N-cyclohexylsulfamoyl group); a sulfo group; a phosphonyl group (a phosphonyl group having preferably from 1 to 32 carbon atoms, more preferably from 1 to 24 carbon atoms, such as a phenoxyphosphonyl group, an octyloxyphosphonyl group, or a phenylphosphonyl group); and a phosphinoylamino group (a phosphinoylamino group having preferably from 1 to 32 carbon atoms, more preferably from 1 to 24 carbon atoms, such as a diethoxyphosphinoylamino group or a dioctyloxyphosphinoylamino group).

When any monovalent group selected from those described above can itself be substituted, the monovalent group may be substituted by at least one of the above groups. When two or more substituents are substituted on the monovalent group, the substituents may be the same as each other, or some or all of the substituents may be different from each other.

In Formula (I), R¹ and R² may be bonded to each other to form a five-membered, six-membered, or seven-membered ring, independently of whether or not a ring is formed by bonding of R² and R³, R⁴ and R⁵, or R⁵ and R⁶. R² and R³ may be bonded to each other to form a five-membered, six-membered, or seven-membered ring, independently of whether or not a ring is formed by bonding of R¹ and R², R⁴ and R⁵, or R⁵ and R⁶. R⁴ and R⁵ may be bonded to each other to form a five-membered, six-membered, or seven-membered ring, independently of whether or not a ring is formed by bonding of R¹ and R², R² and R³, or R⁵ and R⁶. R⁵ and R⁶ may be bonded to each other to form a five-membered, six-membered, or seven-membered ring, independently of whether or not a ring is formed by bonding of R¹ and R², R² and R³, or R⁴ and R⁵. The ring that any one pair of R¹ and R², R² and R³, R⁴ and R⁵, or R⁵ and R⁶ may form by mutual bonding may be a saturated ring or an unsaturated ring. Examples of the five-membered, six-membered, or seven-membered, saturated or unsaturated ring include a pyrrole ring, a furan ring, a thiophene ring, a pyrazole ring, an imidazole ring, a triazole ring, an oxazole ring, a thiazole ring, a pyrrolidine ring, a piperidine ring, a cyclopentene ring, a cyclohexene ring, a benzene ring, a pyridine ring, a pyrazine ring, and a pyridazine ring, and preferable examples include a benzene ring and a pyridine ring.

When the five-membered, six-membered, or seven-membered ring formed can be substituted, the ring may be substituted by at least one of the substituents R. When two or more substituents are substituted on the ring, the substituents may be the same as each other, or some or all of the substituents may be different from each other.

Next, the metal atom or metal compound of the specific complex is described.

The metal or metal compound to be used may be any metal atom or metal compound capable of forming a complex, and examples thereof include a divalent metal atom, a divalent metal oxide, a divalent metal hydroxide, and a divalent metal chloride. Specifically, examples thereof include: a metal such as Zn, Mg, Si, Sn, Rh, Pt, Pd, Mo, Mn, Pb, Cu, Ni, Co, or Fe; a metal chloride such as AlCl₃, InCl₃, FeCl₂, TiCl₂, SnCl₂, SiCl₂, or GeCl₂: a metal oxide such as TiO or VO; and a metal hydroxide such as Si(OH)₂.

Among them, Fe, Zn, Mg, Si, Pt, Pd, Mo, Mn, Cu, Ni, Co, TiO, or VO is preferable, Fe, Zn, Mg, Si, Pt, Pd, Cu, Ni, Co, or VO is more preferable, and Fe, Zn, Cu, Co, or VO (V═O) is most preferable, from the viewpoints of stability, spectral properties, thermal resistance, light fastness, and production suitability of the complex.

Preferable embodiments of the complex in which a compound represented by Formula (I) coordinates to a metal atom or metal compound include those described below.

In a preferable embodiment, in Formula (I), R¹ and R⁶ each independently represent a hydrogen atom, an alkyl group, an alkenyl group, an aryl group, a heterocyclic group, a silyl group, a hydroxyl group, a cyano group, an alkoxy group, an aryloxy group, a heterocyclic oxy group, an acyl group, an alkoxycarbonyl group, a carbamoyl group, an amino group, an anilino group, a heterocyclic amino group, a carbonamido group, a ureido group, an imido group, an alkoxycarbonylamino group, an aryloxycarbonylamino group, a sulfonamido group, an azo group, an alkylthio group, an arylthio group, a heterocyclylthio group, an alkylsulfonyl group, an arylsulfonyl group, or a phosphinoylamino group; R² and R⁵ each independently represent a hydrogen atom, a halogen atom, an alkyl group, an alkenyl group, an aryl group, a heterocyclic group, a hydroxyl group, a cyano group, a nitro group, an alkoxy group, an aryloxy group, a heterocyclic oxy group, an acyl group, an alkoxycarbonyl group, an aryloxycarbonyl group, a carbamoyl group, an imido group, an alkoxycarbonylamino group, a sulfonamido group, an azo group, an alkylthio group, an arylthio group, a heterocyclylthio group, an alkylsulfonyl group, an arylsulfonyl group, or a sulfamoyl group; R³ and R⁴ each independently represent a hydrogen atom, a halogen atom, an alkyl group, an alkenyl group, an aryl group, a heterocyclic group, a silyl group, a hydroxyl group, a cyano group, an alkoxy group, an aryloxy group, a heterocyclic oxy group, an acyl group, an alkoxycarbonyl group, a carbamoyl group, an anilino group, a carbonamido group, a ureido group, an imido group, an alkoxycarbonylamino group, a sulfonamido group, an azo group, an alkylthio group, an arylthio group, a heterocyclylthio group, an alkylsulfonyl group, an arylsulfonyl group, a sulfamoyl group, or a phosphinoylamino group; R⁷ represents a hydrogen atom, a halogen atom, an alkyl group, an aryl group, or a heterocyclic group; and the metal atom or metal compound is Zn, Mg, Si, Pt, Pd, Mo, Mn, Cu, Ni, Co, TiO, or VO.

In a more preferable embodiment of the complex in which a compound represented by Formula (I) coordinates to a metal atom or metal compound, in Formula (I), R¹ and R⁶ each independently represent a hydrogen atom, an alkyl group, an alkenyl group, an aryl group, a heterocyclic group, a cyano group, an acyl group, an alkoxycarbonyl group a carbamoyl group, an amino group, a heterocyclic amino group, a carbonamido group, a ureido group, an imido group, an alkoxycarbonylamino group, an aryloxycarbonylamino group, a sulfonamido group, an azo group, an alkylsulfonyl group, an arylsulfonyl group, or a phosphinoylamino group; R² and R⁵ each independently represent an alkyl group, an alkenyl group, an aryl group, a heterocyclic group, a cyano group, a nitro group, an acyl group, an alkoxycarbonyl group, an aryloxycarbonyl group, a carbamoyl group, an imido group, an alkylsulfonyl group, an arylsulfonyl group, or a sulfamoyl group; R³ and R⁴ each independently represent a hydrogen atom, an alkyl group, an alkenyl group, an aryl group, a heterocyclic group, a cyano group, an acyl group, an alkoxycarbonyl group, a carbamoyl group, a carbonamido group, a ureido group, an imido group, an alkoxycarbonylamino group, a sulfonamido group, an alkylthio group, an arylthio group, a heterocyclylthio group, an alkylsulfonyl group, an arylsulfonyl group, or a sulfamoyl group; R⁷ represents a hydrogen atom, a halogen atom, an alkyl group, an aryl group, or a heterocyclic group; and the metal atom or metal compound is Zn, Mg, Si, Pt, Pd, Cu, Ni, Co, or VO.

In a particularly preferable embodiment of the complex in which a compound represented by Formula (I) coordinates to a metal atom or metal compound, in Formula (I), R¹ and R⁶ each independently represent a hydrogen atom, an alkyl group, an aryl group, a heterocyclic group, an amino group, a heterocyclic amino group, a carbonamido group, a ureido group, an imido group, an alkoxycarbonylamino group, a sulfonamido group, an azo group, an alkylsulfonyl group, an arylsulfonyl group, or a phosphinoylamino group; R² and R⁵ each independently represent an alkyl group, an aryl group, a heterocyclic group, a cyano group, an acyl group, an alkoxycarbonyl group, a carbamoyl group, an alkylsulfonyl group, or an arylsulfonyl group; R³ and R⁴ each independently represent a hydrogen atom, an alkyl group, an aryl group, or a heterocyclic group; R⁷ represents a hydrogen atom, an alkyl group, an aryl group, or a heterocyclic group; and the metal atom or metal compound is Zn, Cu, Co, or VO.

In Formula (I), it is preferable that R³ and R⁴ each represent a phenyl group, in view of obtaining excellent fastness. The reasons therefor are thought to be as follows: (1) As a result of R³ and R⁴ each representing a phenyl group, the absorption spectrum of the compound shift to the longer wavelength side, so that an overlap with the absorption spectrum (around 550 nm) of the phthalocyanine pigment to be used together becomes large, and energy transfer therebetween is facilitated, and (2) the presence of the sterically bulky substituents enhances the fastness of the compound.

In Formula (I), it is preferable that at least one of R² or R⁵ represents a 2,6-di-tert-butyl-4-methycyclohexyloxycarbonyl group, in view of obtaining excellent solvent solubility.

Specific examples of the specific complex in the invention are shown below. However, the invention is not limited thereto.

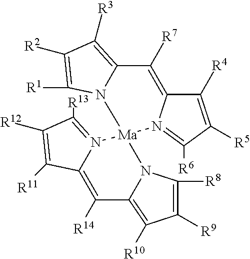

| Com- | | | | | |
|---|---|---|---|---|---|
| pound | | | | | |
| No. | R¹═R⁶═R⁸═R¹³ | R²═R⁵═R⁹═R¹² | R³═R⁴═R¹⁰═R¹¹ | R⁷═R¹⁴ | Ma |
| Ia-3 | —NH₂ | 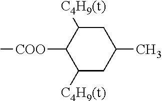 | —CH₃ | —H | Zn |
| Ia-4 | —NH₂ | 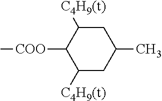 | —CH₃ | —H | V═O |
| Ia-5 | —NHCOCH₃ | | —CH₃ | —H | Zn |
| Ia-6 | —NHCOCH₃ 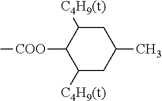 | 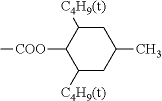 | —CH₃ | —H | Cu |
| Ia-7 | —NHCOCH₃ | 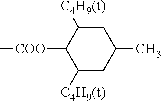 | —CH₃ | —CH₃ | Zn |
| Ia-8 | —NHCOCH₂OCH₂COOH | 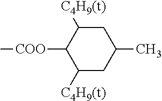 | —CH₃ | —CH₃ | Zn |
| Ia-9 | —NHCOCH₂OCH₂COOH | 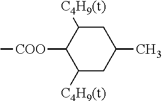 | —CH₃ | —CH₃ | Zn |
| Ia-10 | —NHCOCH₂OCH₂COOH | 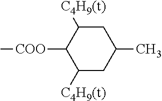 | —C₃H₇(iso) | —H | Zn |
| Ia-11 | —NHCOCH₂OCH₂COOH | 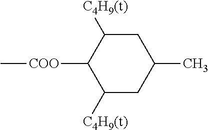 | —C₃H₇(iso) | —CH₃ | Zn |
| Ia-12 | —NHCOCH₂OCH₂COOH | 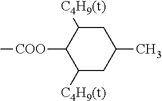 | —C₄H₉(t) | —H | Cu |
| Ia-13 | —NH₂ | 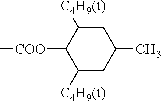 | —C₄H₉(t) | —CH₃ | Zn |
| Ia-14 | —NH₂ | 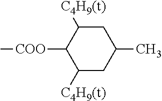 | —C₄H₉(t) | —H | Zn |
| Ia-15 | —NH₂ | 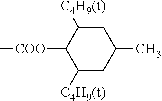 | 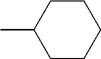 | —H | Zn |
| Ia-16 | —NHCOCH₃ | 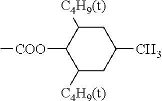 | 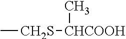 | —CH₃ | Cu |
| Ia-17 | —NH₂ | 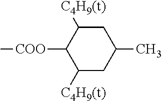 | 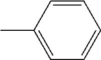 | —H | Zn |
| Ia-18 | —NH₂ | 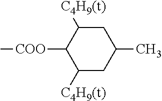 | 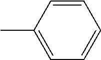 | —H | Cu |
| Ia-19 | —NH₂ | 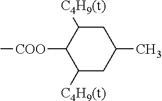 | 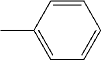 | —H | V═O |
| Ia-20 | —NH₂ | 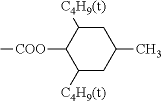 | 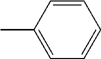 | —CH₃ | Zn |
| Ia-21 | —NHCOCH₃ | 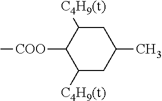 | 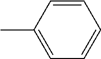 | —CH₃ | Zn |
| Ia-22 | —NHCOCH₂OCH₂COOH | 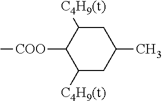 | 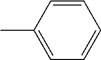 | —H | Zn |
| Ia-23 | —NHCOCH₂OCH₂COOH | 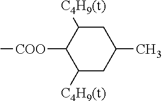 | 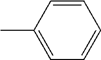 | —CH₃ | Zn |
| Ia-24 | —NHCOCH₂OCH₂COOH | 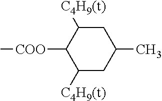 | 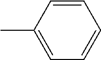 | —CH₃ | Cu |
| Ia-25 | —NHCOCH₂OCH₂COOH | 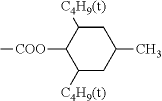 | 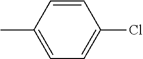 | —CH₃ | Zn |
| Ia-26 | —NHCOCH₂OCH₂COOH | 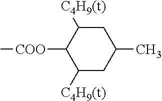 | 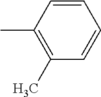 | —CH₃ | Zn |
| Ia-27 | 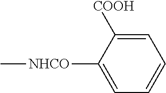 | 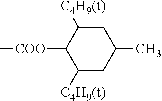 | —CH₃ | —H | Cu |
| Ia-28 | 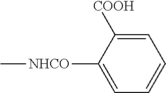 | 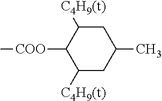 | —CH₃ | —CH₃ | Zn |
| Ia-29 | 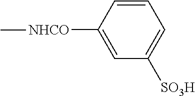 | 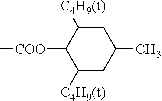 | —CH₃ | —CH₃ | Cu |
| Ia-30 | 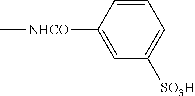 | 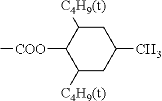 | 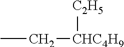 | —CH₃ | Cu |
| Ia-31 | 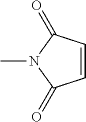 | 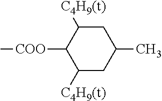 | 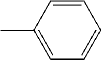 | —CH₃ | Zn |
| Ia-32 | 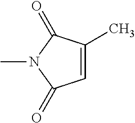 | 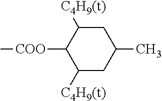 | 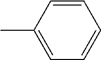 | —CH₃ | Zn |
| Ia-33 | —NHSO₂CH₃ | 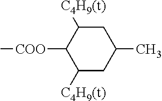 | —CH₃ | —CH₃ | Zn |
| Ia-34 | 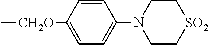 | 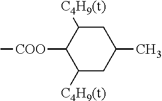 | —CH₃ | —CH₃ | Zn |
| Ia-35 | 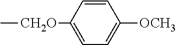 | 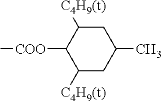 | 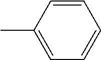 | —CH₃ | Zn |
| Ia-36 | 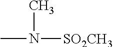 | 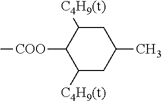 | 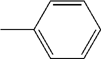 | —CH₃ | Zn |
| Ia-37 | 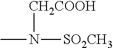 | 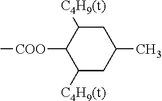 | 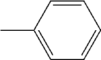 | —CH₃ | Zn |
| Ia-38 | —Cl | 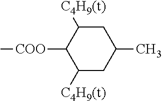 | 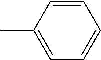 | —CH₃ | Cu |
| Ia-39 | —S—CH₂COOH | 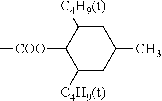 | 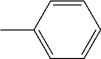 | —CH₃ | Cu |
| Ia-40 | 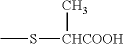 | 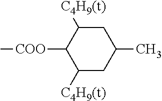 | —CH₃ | —CH₃ | Cu |
| Ia-41 | 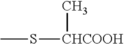 | 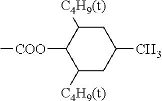 | —CH₃ | —CH₃ | V═O |
| Ia-42 | —SO₂CH₃ | 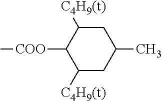 | —CH₃ | —CH₃ | V═O |
| Ia-43 | —SO₂CH₃ | 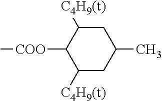 | 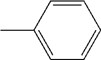 | —CH₃ | Cu |
| Ia-44 | 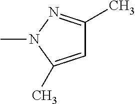 | 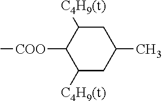 | 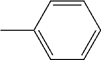 | —CH₃ | Cu |
| Ia-45 | —CH₃ | 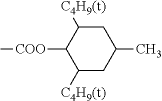 | —CH₃ | —H | Cu |
| Ia-46 | —CH₃ | 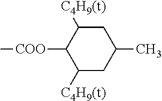 | —CH₃ | —CH₃ | Zn |
| Ia-47 | —CH₃ | 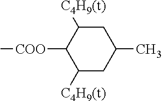 | —CH₃ | —CH₃ | Cu |
| Ia-48 | —CH₃ | 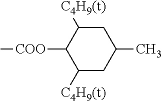 | —CH₃ | —CH₃ | Ni |
| Ia-49 | —C₄H₉(t) | 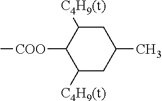 | —CH₃ | —CH₃ | Zn |
| Ia-50 | —C₄H₉(t) | 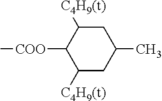 | —CH₃ | —CH₃ | Pd |
| Ia-51 | —CH₂CH₂COOH | 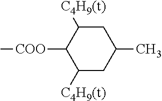 | —CH₃ | —CH₃ | Zn |
| Ia-52 | —CH₂CH₂COOH | 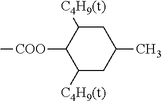 | 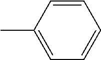 | —CH₃ | Zn |
| Ia-53 | —CH₃ | 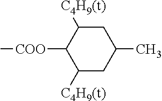 | 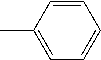 | —CH₃ | Zn |
| Ia-54 | —CH₃ | 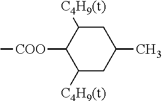 | 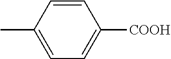 | —CH₃ | Zn |
| Ia-55 | —CH₃ | 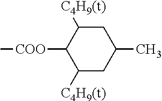 | 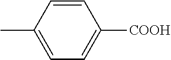 | —CH₃ | Cu |
| Ia-56 | —CH₃ | 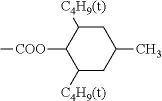 | 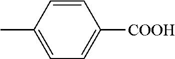 | 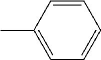 | Zn |
| Ia-57 | 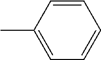 | 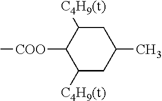 | —CH₃ | —H | Zn |
| Ia-58 | 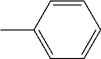 | 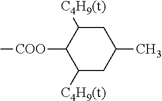 | —CH₃ | —CH₃ | Zn |
| Ia-59 | 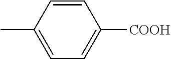 | 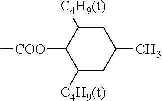 | 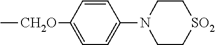 | —CH₃ | Zn |
| Ia-60 | 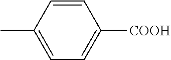 | 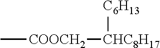 | 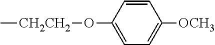 | —CH₃ | Zn |
| Ia-61 | 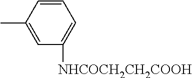 | 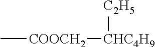 | 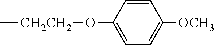 | —CH₃ | Zn |
| Ia-62 | 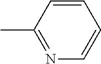 | 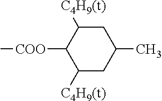 | 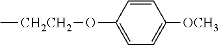 | —CH₃ | Zn |
| Ia-63 | —CH₃ | 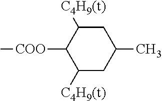 | 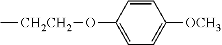 | —CH₃ | Cu |
| Ia-67 | —NH₂ | —CN | —CH₃ | —H | Zn |
| Ia-68 | —NHCOCH₃ | —CN | —CH₃ | —CH₃ | Zn |
| Ia-69 | —CH₃ | —CN | —CH₃ | —CH₃ | Zn |
| Ia-70 | —CH₃ | —CN | 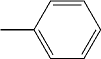 | —CH₃ | Zn |
| Ia-71 | —C₁₃H₂₇ | —CN | —CH₃ | 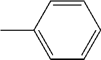 | Cu |
| Ia-72 | —NH₂ | —CN | —CF₃ | 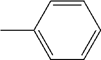 | Cu |
| Ia-73 | —NHCOCH₂OCH₂COOH | —CN | —CF₃ | 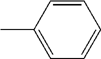 | Cu |
| Ia-74 | 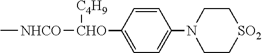 | —CN | —CF₃ | —CH₃ | Zn |
| Ia-75 | 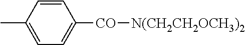 | —CN | —C₃H₇(iso) | —CH₃ | Zn |
| Ia-76 | 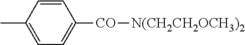 | —CN | 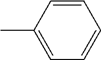 | —CH₃ | Zn |
| Ia-77 | 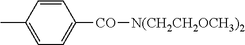 | —CN | —CF₃ | —CH₃ | Zn |
| Ia-78 | —NHCOCH₂OCH₂COOH | —CN | 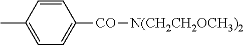 | —CH₃ | Zn |
| Ia-79 | 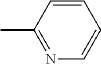 | 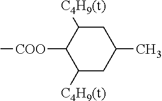 | 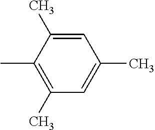 | —H | Zn |
| Ia-80 | 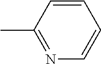 | 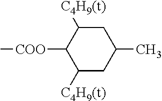 | —C₄H₉(t) | —H | Zn |
| Ia-81 | —C₁₃H₂₇ | 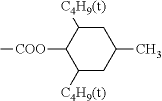 | 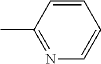 | —H | Zn |
| Ia-82 | —NHCOCH₂OCH₂COOH | —COOC₂H₅ | 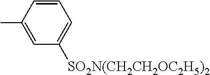 | —H | Cu |
| Ia-83 | 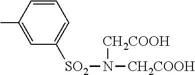 | 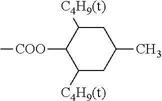 | —CH₃ | —H | Zn |

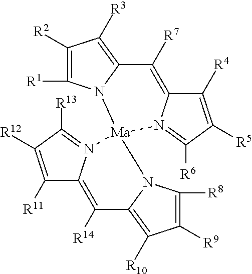

| Compound | | | | | |
|---|---|---|---|---|---|
| No. | R¹═ R⁶═R⁸═R¹³ | R²═R⁵═R⁹═R¹² | R³═R⁴═R¹⁰═R¹¹ | R⁷═R¹⁴ | Ma |
| Ia-A | —NHCOCH₃ | 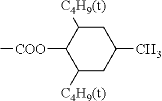 | —CH₃ | 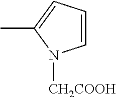 | Zn |

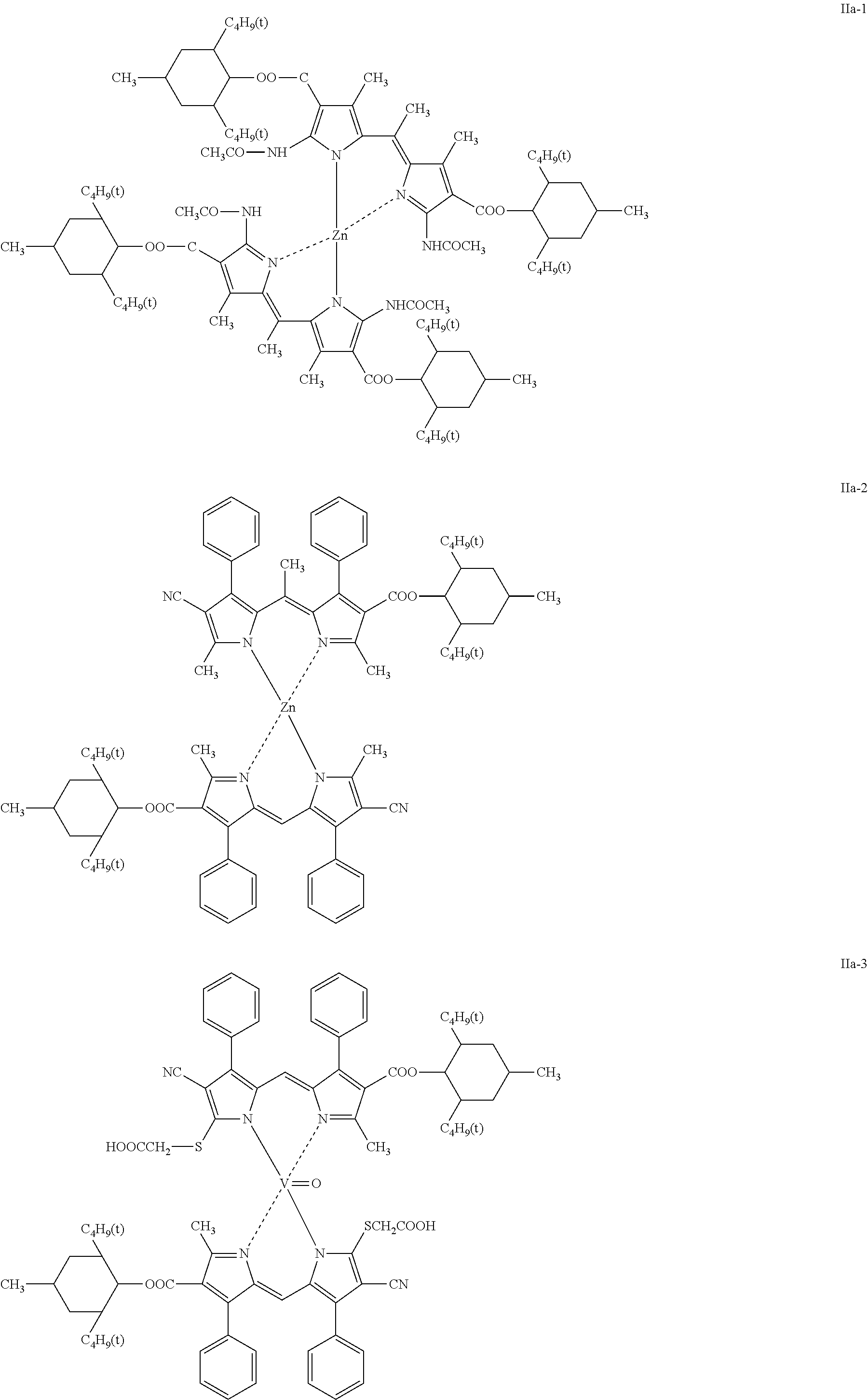

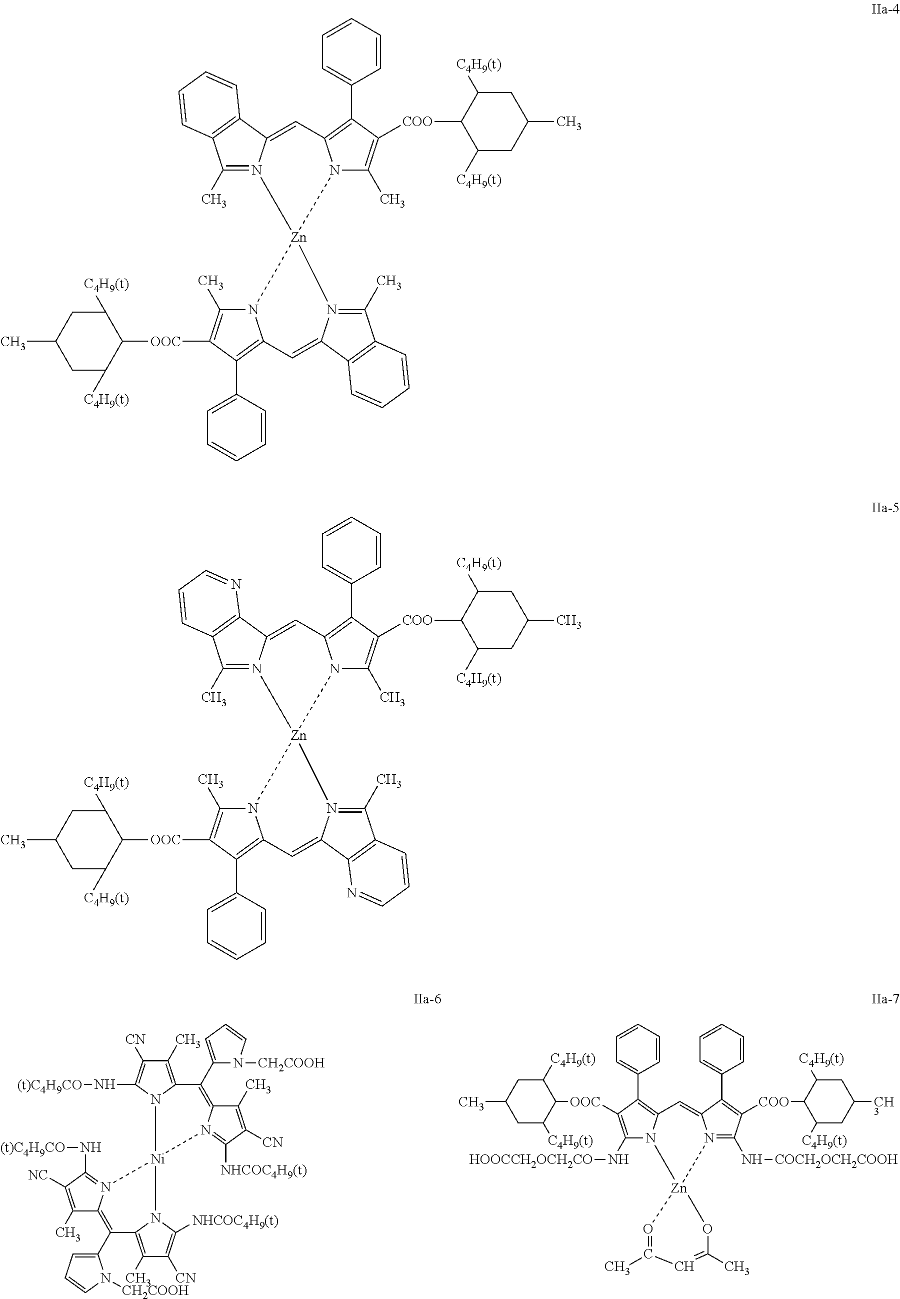

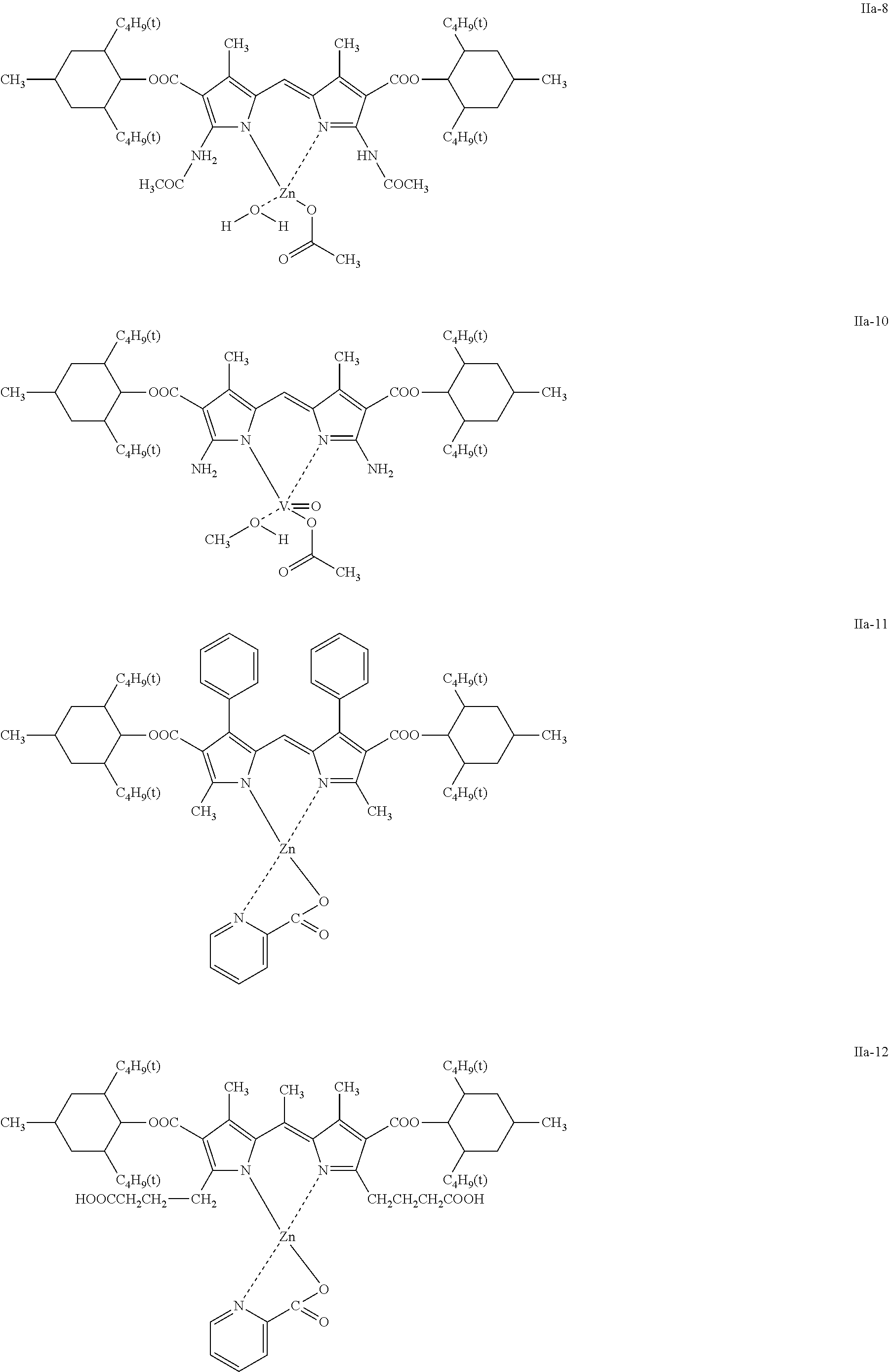

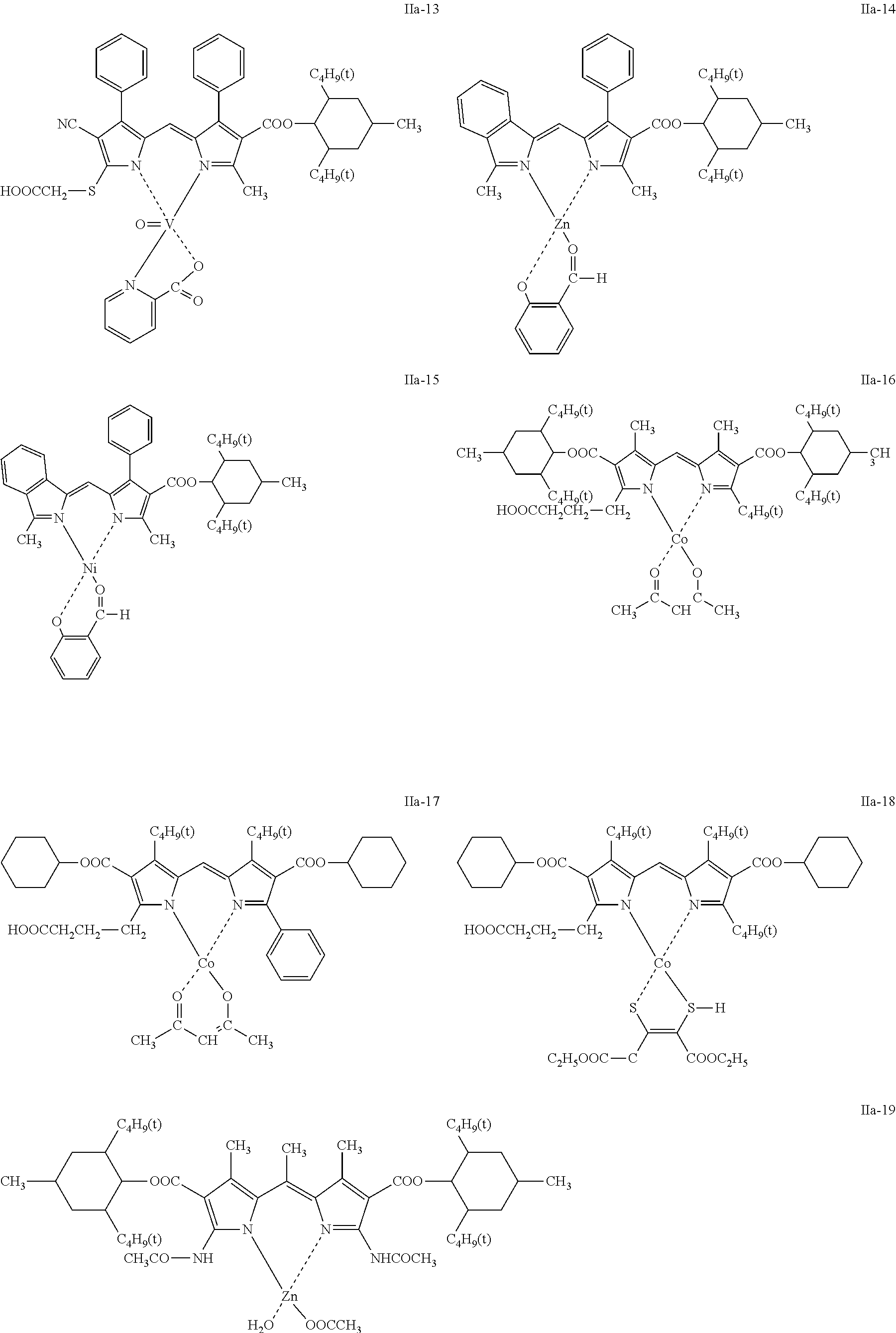

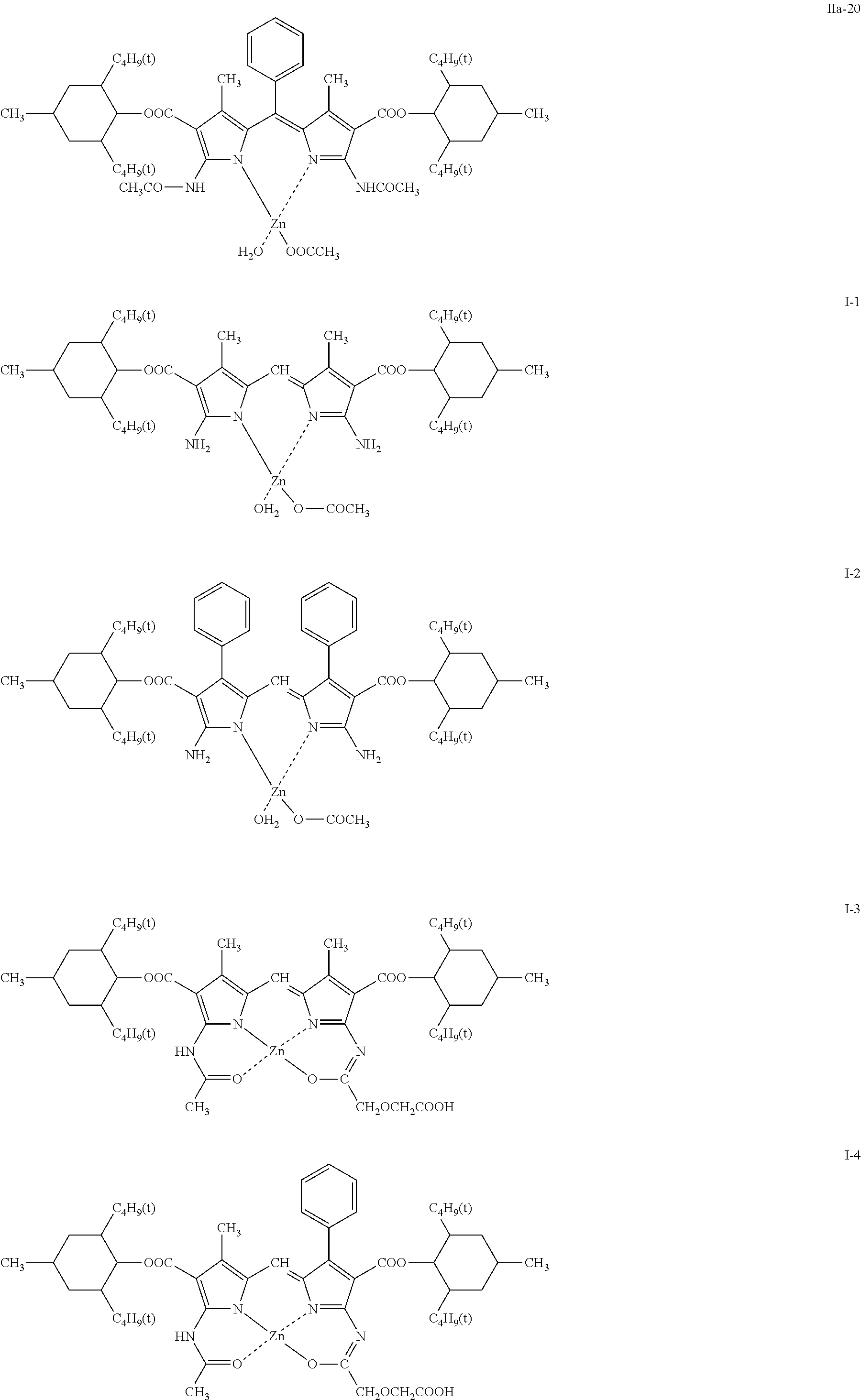

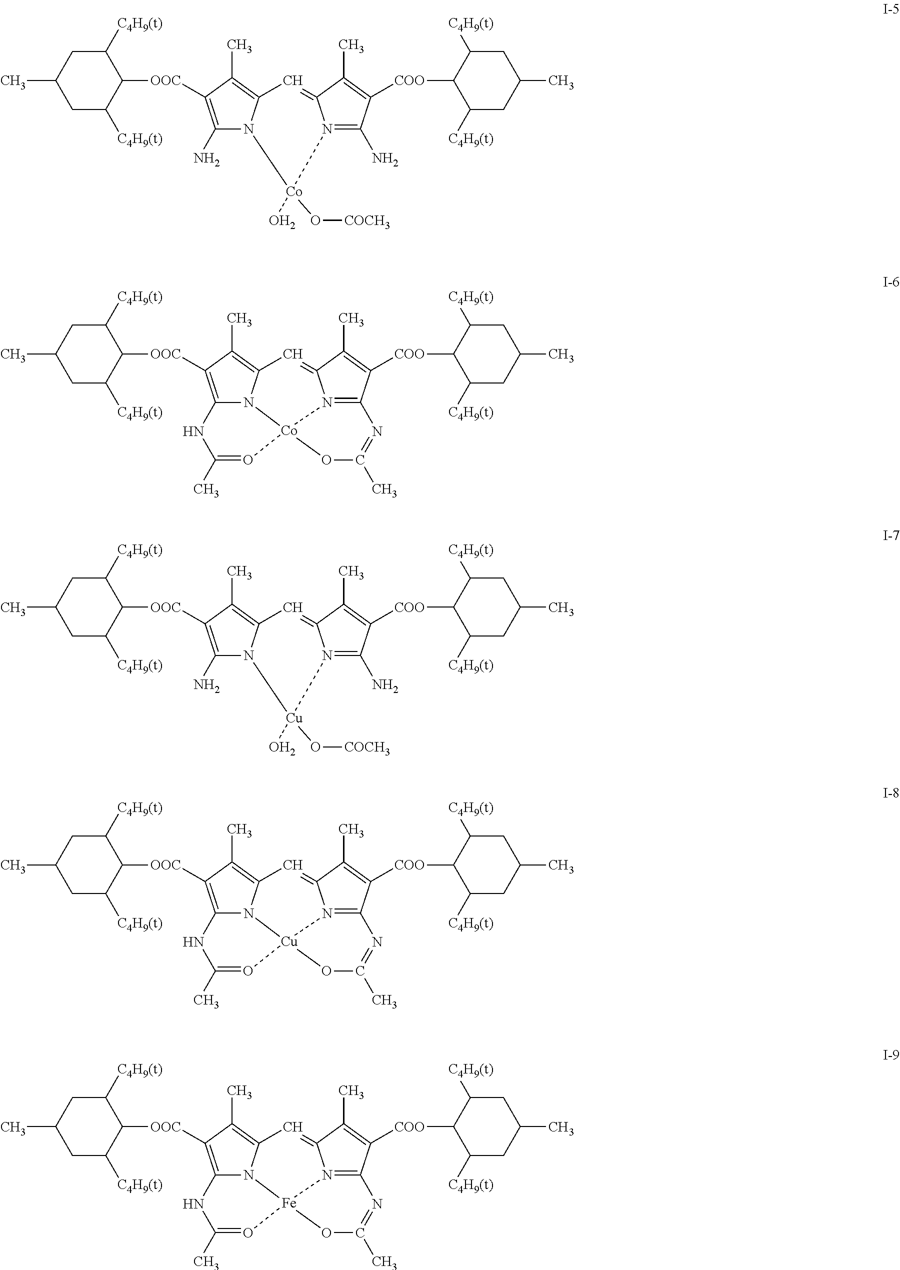

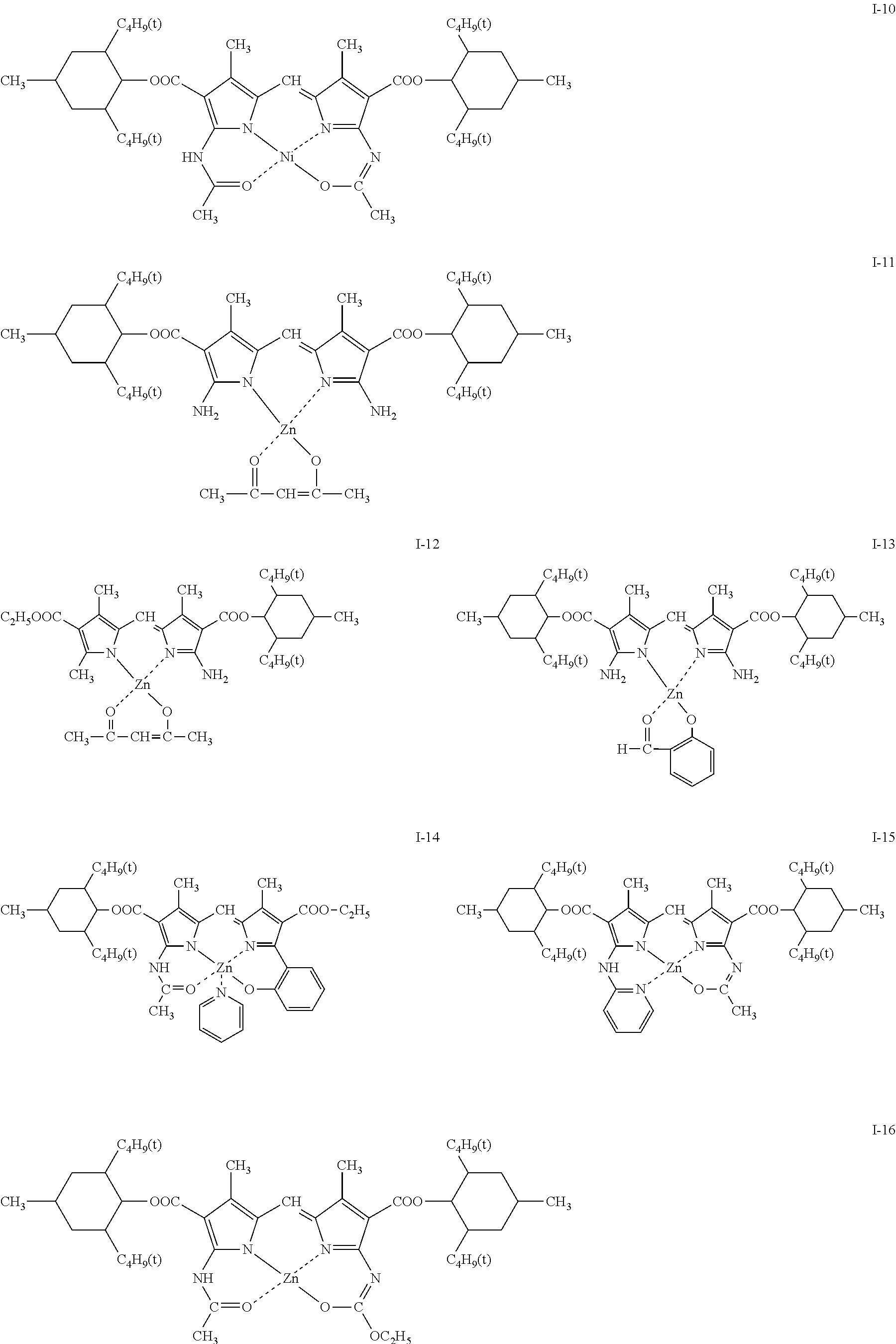

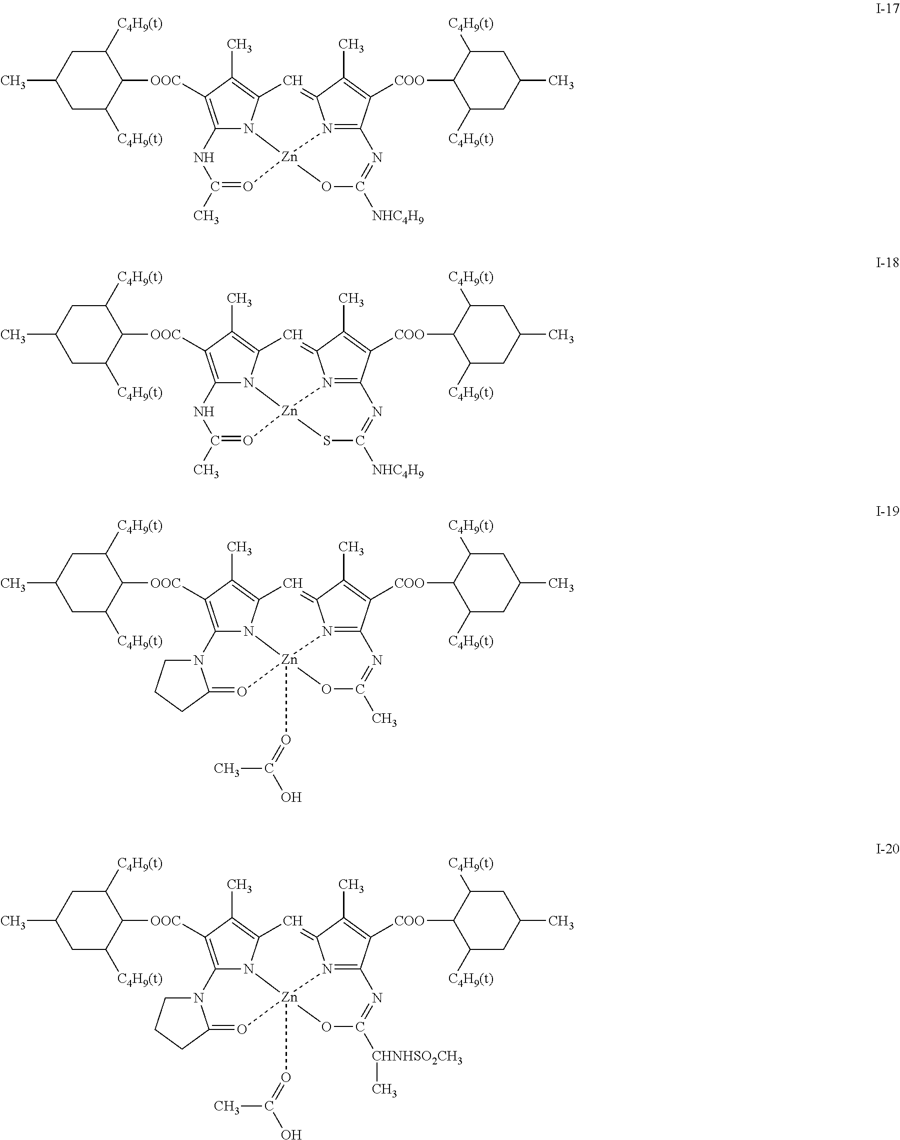

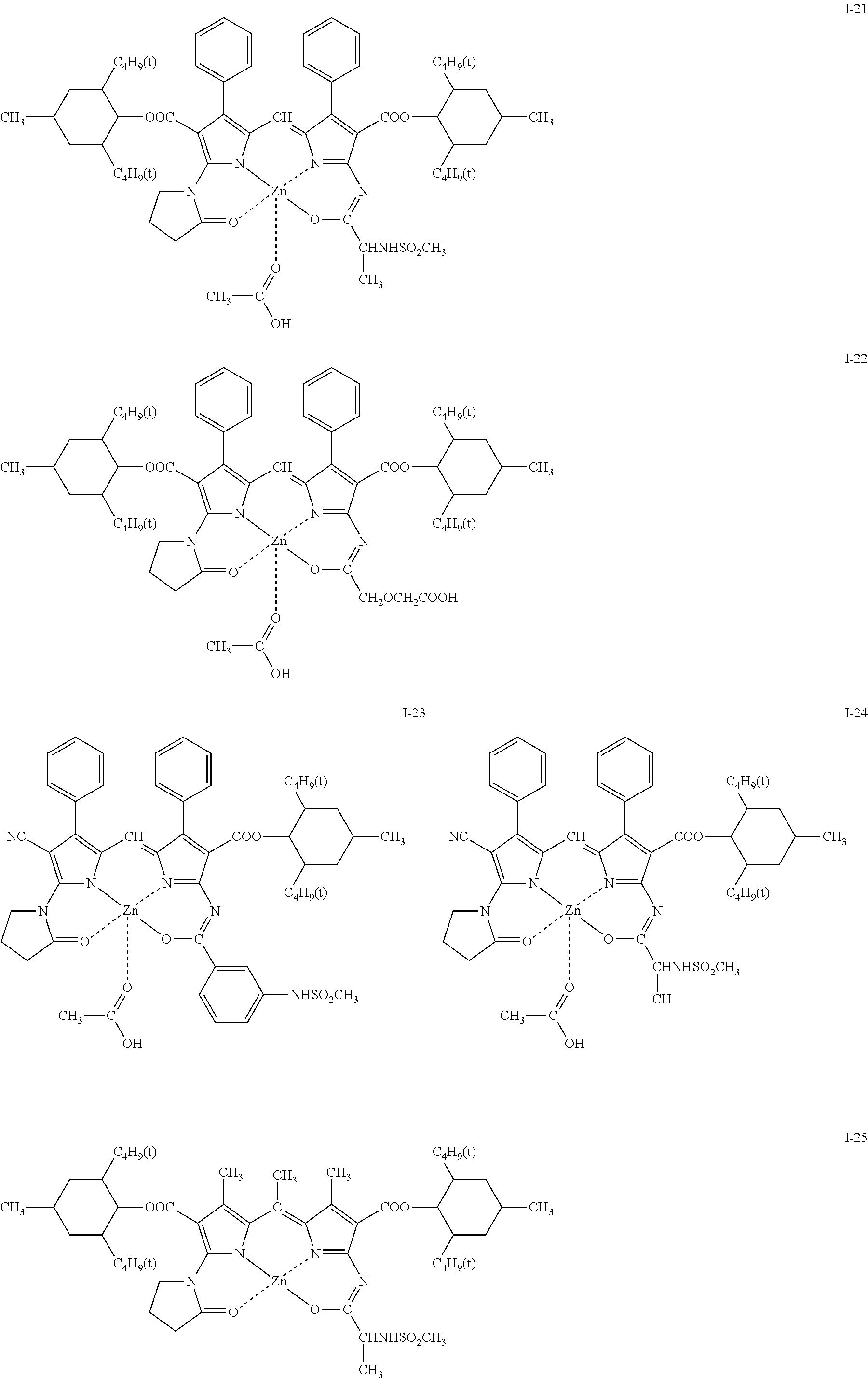

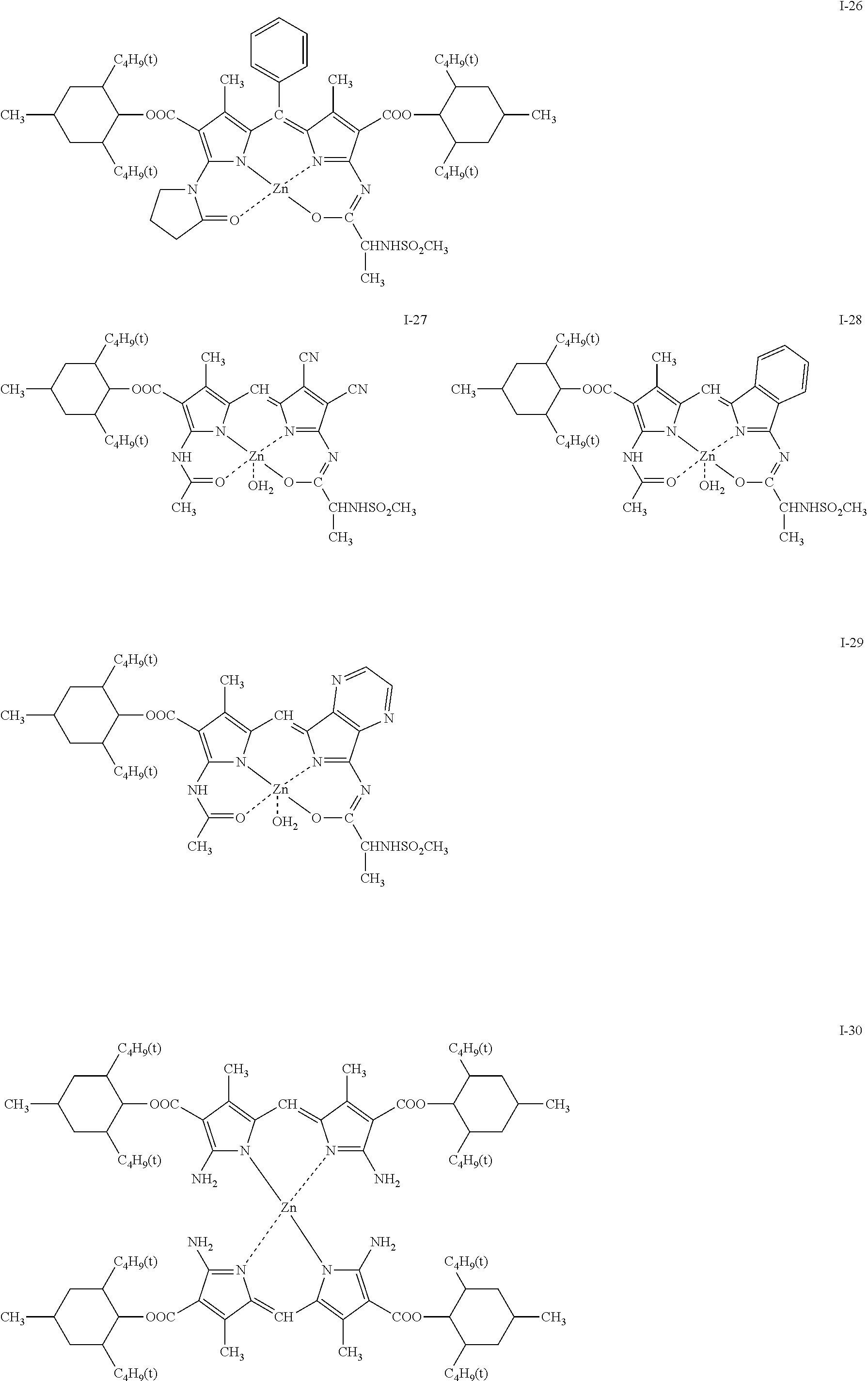

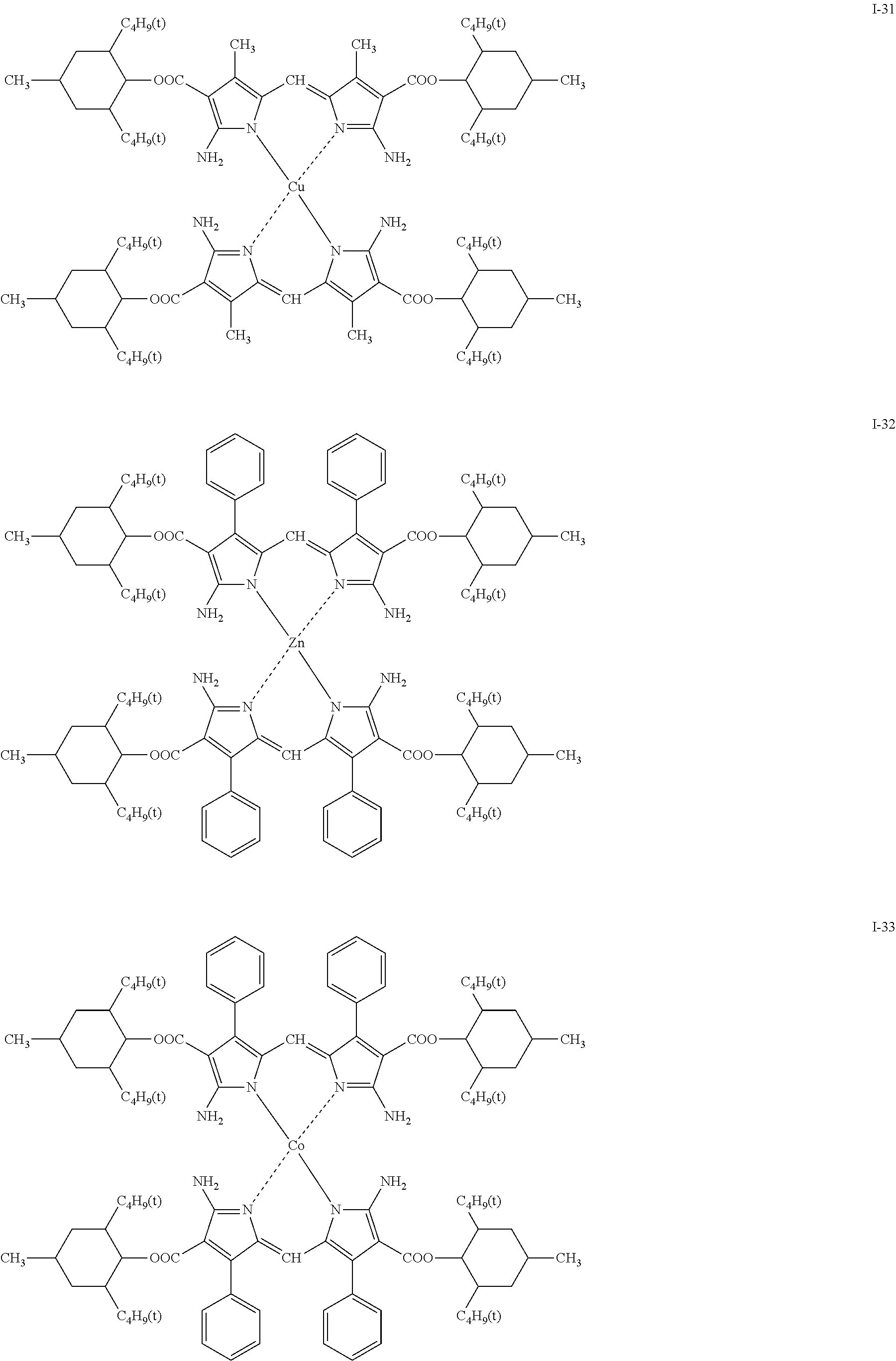

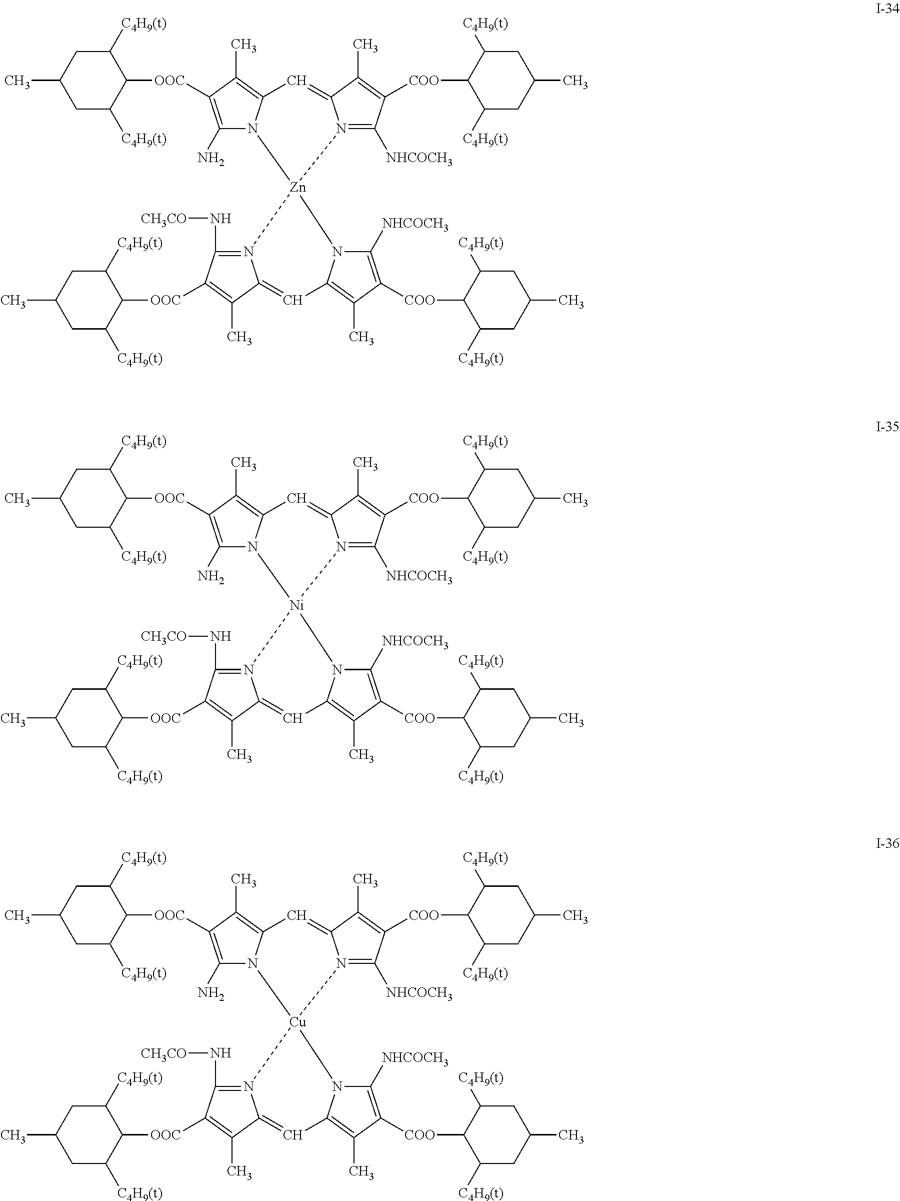

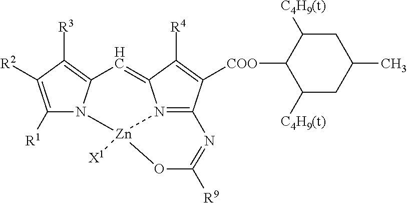

| Compound | | | | | | |
|---|---|---|---|---|---|---|
| No. | R¹ | R² | R³ | R⁴ | R⁹ | X¹ |
| II-1 | —CH₃ | —COOC₂H₅ | —CH₃ | —CH₃ | —CH₃ | H₂O |
| II-2 | —CH₃ | —COOC₂H₅ | —CH₃ | —CH₃ | 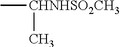 | H₂O |
| II-3 | —CH₃ | —COOC₂H₅ | —CH₃ | —CH₃ | 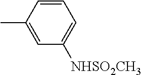 | H₂O |
| II-4 | 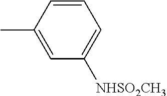 | —COOCH₃ | —CH₃ | 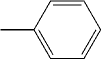 | —CH₃ | H₂O |
| II-5 | 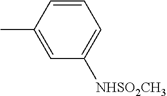 | —COOC₂H₅ | —CH₃ | 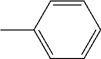 | —CH₂OCH₂COOH | H₂O |
| II-6 | 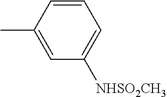 | —COOC₂H₅ | —CH₃ | 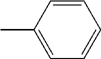 | —CH₃ | H₂O |

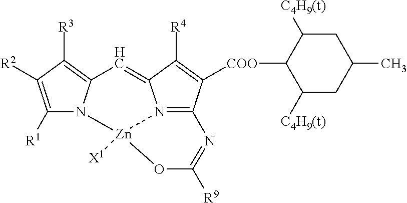

| Compound | | | | | | |
|---|---|---|---|---|---|---|
| No. | R¹ | R² | R³ | R⁴ | R⁹ | X¹ |
| II-7 | —CH₃ | —COOC₂H₅ | 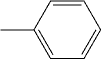 | 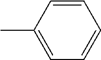 | —CH₃ | H₂O |
| II-8 | 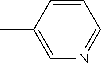 | —COOC₂H₅ | 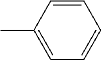 | 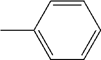 | —CH₃ | H₂O |
| II-9 | 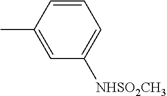 | —CN | —CH₃ | —CH₃ | —CH₃ | H₂O |
| II-10 | 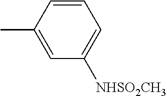 | —CN | —CH₃ | —CH₃ | 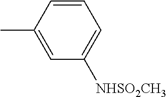 | H₂O |
| II-11 | 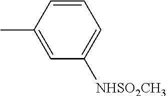 | —CN | 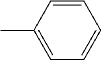 | 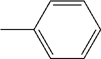 | —CH₃ | H₂O |

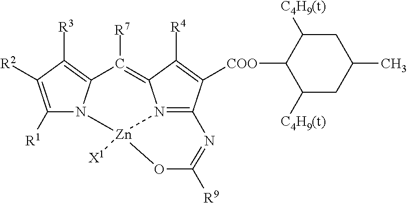

| Compound | | | | | | | |
|---|---|---|---|---|---|---|---|
| No. | R¹ | R² | R³ | R⁴ | R⁷ | R⁹ | X¹ |
| II-A | —CH₃ | —COOC₂H₅ | —CH₃ | —CH₃ | 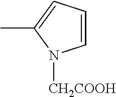 | —CH₃ | —H₂O |

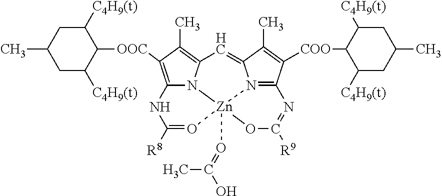

| Com- | | |
|---|---|---|
| pound | | |
| No. | R⁸ | R⁹ |
| III-1 | —CH₃ | —CH₃ |
| III-2 | 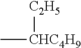 | —CH₃ |
| III-3 | —C₄H₉(t) | —CH₃ |
| III-4 | 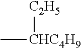 | 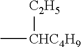 |
| III-5 | —C₄H₉(t) | —C₄H₉(t) |
| III-6 | 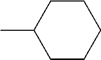 | —CH₃ |
| III-7 | 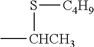 | —CH₃ |
| III-8 | —CH₂OCH₃ | —CH₃ |
| III-9 | 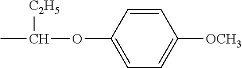 | —CH₃ |
| III-10 | 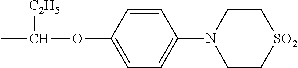 | —CH₃ |
| III-11 | 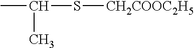 | —CH₃ |
| III-12 | 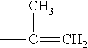 | —CH₃ |
| III-13 | 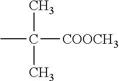 | —CH₃ |
| III-14 | 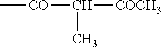 | —CH₃ |
| III-15 | —CH₂OCH₂COOC₂H₅ | —CH₃ |
| III-16 | —CH₂NHSO₂CH₃ | —CH₃ |
| III-17 | 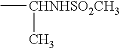 | —CH₃ |
| III-18 | 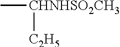 | —CH₃ |
| III-19 | 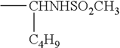 | —CH₃ |
| III-20 | 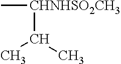 | —CH₃ |
| III-21 | 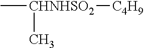 | —CH₃ |
| III-22 | 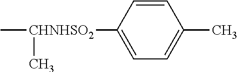 | —CH₃ |
| III-23 | 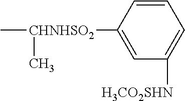 | —CH₃ |
| III-24 | 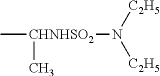 | —CH₃ |

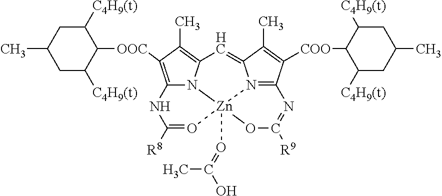

| Compound | | |
|---|---|---|
| No. | R⁸ | R⁹ |
| III-25 | 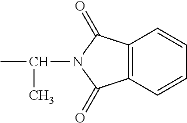 | —CH₃ |
| III-26 | —CH₂CH₂COOC₂H₅ | —CH₃ |
| III-27 | 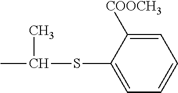 | —CH₃ |
| III-28 | 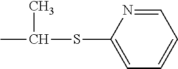 | —CH₃ |
| III-29 | —CH₂NHSO₂CH₃ | —CH₂NHSO₂CH₃ |
| III-30 | 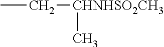 | 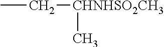 |
| III-31 | —CH₂NHSO₂CH₃ | 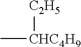 |
| III-32 | 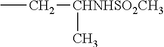 | —C₄H₉(t) |
| III-33 | 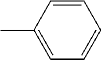 | —CH₃ |
| III-34 | 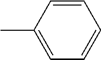 | 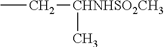 |

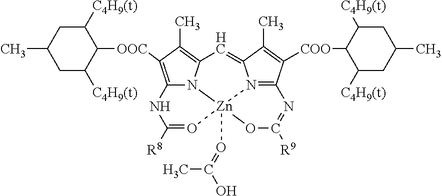

| Com- | | |
|---|---|---|
| pound | | |
| No. | R⁸ | R⁹ |
| III-35 | 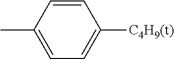 | —CH₃ |
| III-36 | 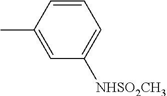 | —CH₃ |
| III-37 | 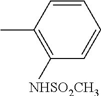 | —CH₃ |
| III-38 | 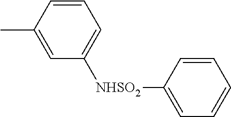 | —CH₃ |
| III-39 | 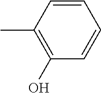 | —CH₃ |
| III-40 | 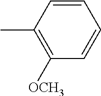 | —CH₃ |
| III-41 | 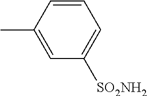 | —CH₃ |
| III-42 | 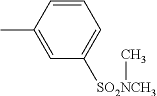 | —CH₃ |
| III-43 | 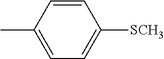 | —CH₃ |
| III-44 | 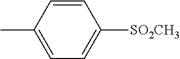 | —CH₃ |

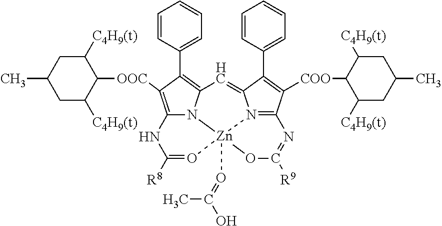

| Com- | | |
|---|---|---|
| pound | | |
| No. | R⁸ | R⁹ |
| III-45 | —CH₃ | —CH₃ |
| III-46 | 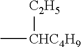 | 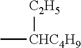 |
| III-47 | —C₄H₉(t) | —C₄H₉(t) |
| III-48 | 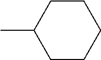 | 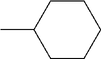 |
| III-49 | —CH₂NHSO₂CH₃ | —CH₃ |
| III-50 | —CH₂NHSO₂CH₃ | —CH₂NHSO₂CH₃ |
| III-51 | 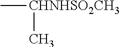 | —CH₃ |
| III-52 | 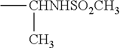 | 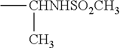 |
| III-53 | 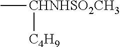 | —CH₃ |
| III-54 | 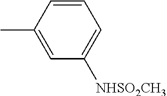 | —CH₃ |
| III-55 | 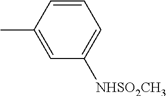 | 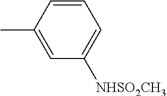 |
| III-56 | 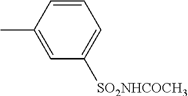 | —CH₃ |

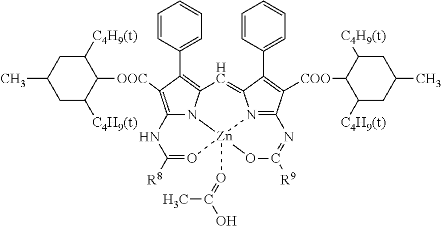

| Com- | | |
|---|---|---|
| pound | | |
| No. | R⁸ | R⁹ |
| III-57 | 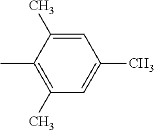 | —CH₃ |
| III-58 | 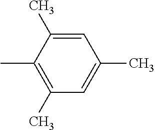 | 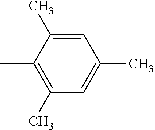 |
| III-59 | 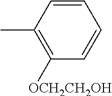 | —CH₃ |
| III-60 | 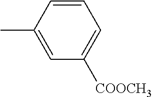 | —CH₃ |
| III-61 | 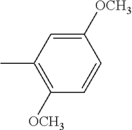 | —CH₃ |
| III-62 | 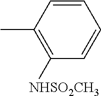 | —CH₃ |
| III-63 | 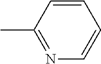 | —CH₃ |
| III-64 | 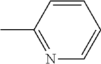 | 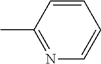 |

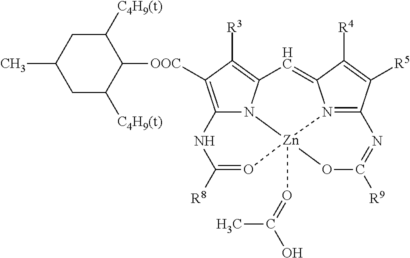

| Com- | | | | | |
|---|---|---|---|---|---|
| pound | | | | | |
| No. | R³ | R⁴ | R⁵ | R⁸ | R⁹ |
| III-65 | —CH₃ | —CH₃ | —COOC₂H₅ | —CH₃ | —CH₃ |
| III-66 | —CH₃ | —CH₃ | —COOC₂H₅ | 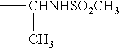 | 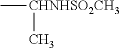 |
| III-67 | —CH₃ | —CH₃ | —COOC₂H₅ | 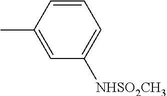 | 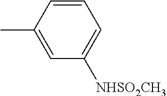 |
| III-68 | 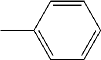 | —CH₃ | —COOC₂H₅ | —CH₃ | —CH₃ |
| III-69 | 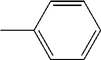 | 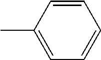 | —COOC₂H₅ | —CH₃ | —CH₃ |
| III-70 | —CH₃ | 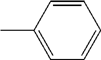 | 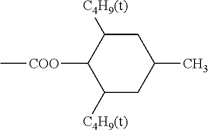 | —CH₃ | 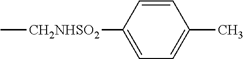 |

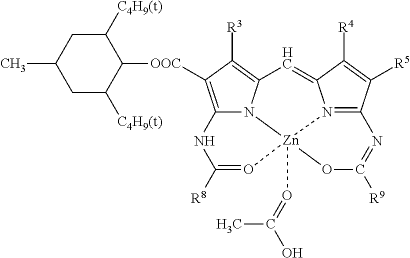

| Compound | | | | | |
|---|---|---|---|---|---|
| No. | R³ | R⁴ | R⁵ | R⁸ | R⁹ |
| III-71 | 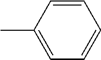 | 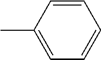 | 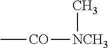 | —CH₃ | 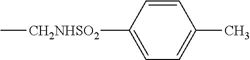 |
| III-72 | 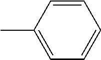 | 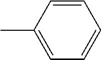 | 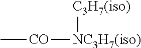 | —CH₃ | 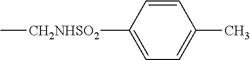 |
| III-73 | 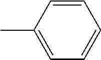 | 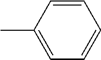 | 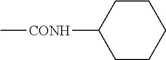 | —CH₃ | 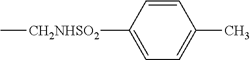 |
| III-74 | 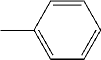 | 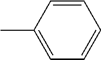 | 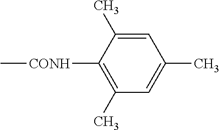 | —CH₃ | 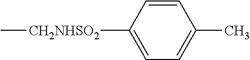 |
| III-75 | 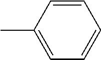 | 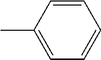 | 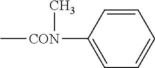 | —CH₃ | 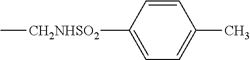 |

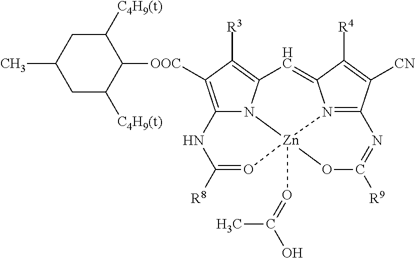

| Compound | | | | |
|---|---|---|---|---|
| No. | R³ | R⁴ | R⁸ | R⁹ |
| III-76 | —CH₃ | —CH₃ | —CH₃ | —CH₃ |
| III-77 | —CH₃ | —CH₃ | 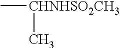 | —CH₃ |
| III-78 | —CH₃ | —CH₃ | 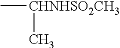 | 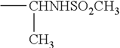 |
| III-79 | —CH₃ | —CH₃ | 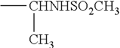 | 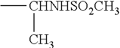 |
| III-80 | —CH₃ | 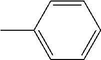 | —CH₃ | —CH₃ |
| III-81 | —CH₃ | 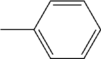 | —CH₃ | 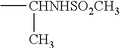 |
| III-82 | —CH₃ | 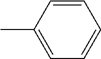 | 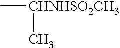 | 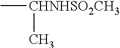 |

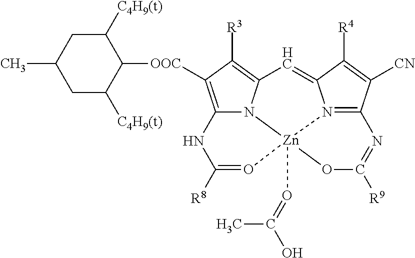

| Compound | | | | |
|---|---|---|---|---|
| No. | R³ | R⁴ | R⁸ | R⁹ |
| III-83 | —CH₃ | 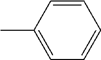 | 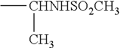 | 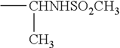 |
| III-84 | —CH₃ | 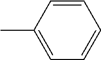 | 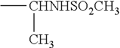 | 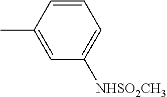 |
| III-85 | —CH₃ | 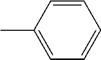 | —C₄H₉(t) | 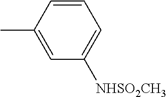 |
| III-86 | 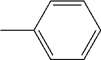 | —CH₃ | —CH₃ | —CH₃ |
| III-87 | 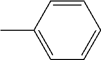 | —CH₃ | —CH₂NHSO₂CH₃ | —CH₂NHSO₂CH₃ |
| III-88 | 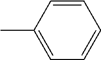 | 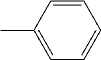 | —CH₃ | —CH₃ |
| III-89 | —CH₃ | 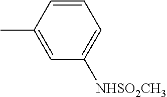 | —CH₃ | —CH₃ |

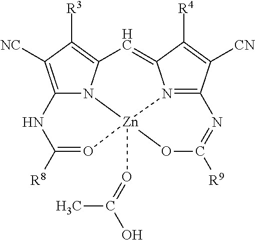

| Compound | | | | |
|---|---|---|---|---|
| No. | R³ | R⁴ | R⁸ | R⁹ |
| III-90 | —CH₃ | —CH₃ | —CH₃ | —CH₃ |
| III-91 | —CH₃ | —CH₃ | —CH₃ | 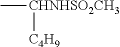 |
| III-92 | —CH₃ | —CH₃ | 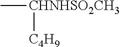 | 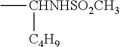 |
| III-93 | 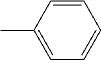 | 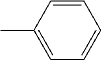 | —CH₃ | —CH₃ |
| III-94 | 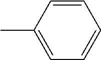 | 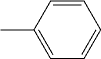 | —C₄H₉(t) | —C₄H₉(t) |
| III-95 | 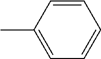 | 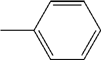 | 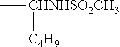 | —C₄H₉(t) |
| III-96 | 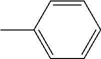 | 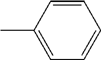 | 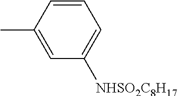 | —CH₃ |
| III-97 | 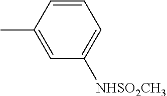 | 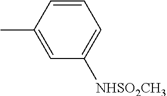 | —CH₃ | —CH₃ |

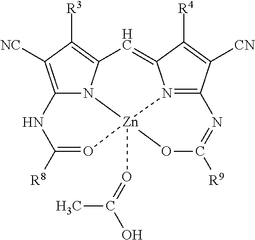

| Compound | | | | |
|---|---|---|---|---|
| No. | R³ | R⁴ | R⁸ | R⁹ |
| III-98 | 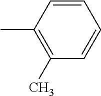 | 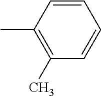 | —CH₃ | —CH₃ |
| III-99 | 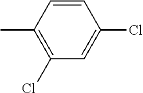 | 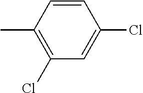 | —CH₃ | —CH₃ |
| III-100 | 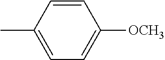 | 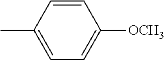 | —CH₃ | —CH₃ |
| III-101 | 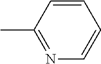 | 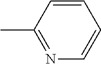 | —CH₃ | —CH₃ |
| III-102 | 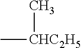 | 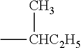 | 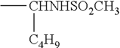 | 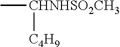 |
| III-103 | 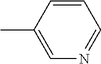 | 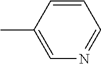 | 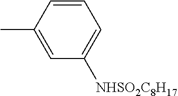 | 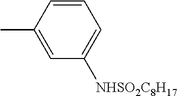 |

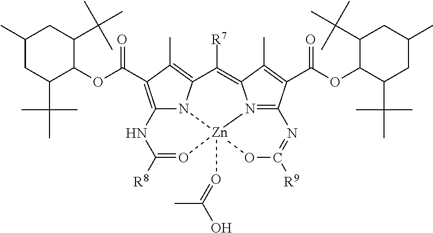

| Compound | | | |
|---|---|---|---|
| No. | R⁷ | R⁸ | R⁹ |
| III-A | 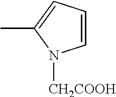 | —C₄H₉(t) | —C₄H₉(t) |

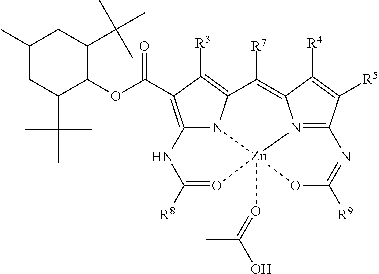

| Com- | | | | | | |
|---|---|---|---|---|---|---|
| pound | | | | | | |
| No. | R³ | R⁴ | R⁵ | R⁷ | R⁸ | R⁹ |
| III-B | —CH₃ | —CH₃ | —COOC₂H₅ | 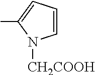 | —CH₃ | —CH₃ |

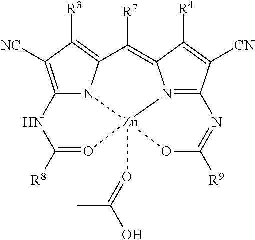

| Compound | | | | | |
|---|---|---|---|---|---|
| No. | R³ | R⁴ | R⁷ | R⁸ | R⁹ |
| III-C | —CH₃ | —CH₃ | 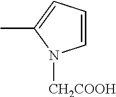 | —CH₃ | —CH₃ |

The molar absorption coefficient of the specific complex in the invention is preferably as high as possible, from the viewpoint of layer thickness. The wavelength of maximum absorbance λmax is preferably from 520 nm to 580 nm, and more preferably from 530 nm to 570 nm, from the viewpoint of improving color purity. The wavelength of maximum absorbance and the molar absorption coefficient are measured with a spectral photometer UV-2400 PC (tradename) manufactured by Shimadzu Corporation.

The melting point of the specific complex in the invention is preferably not excessively high, from the viewpoint of solubility.

The specific complex in the invention can be synthesized according to methods such as those described in U.S. Pat. Nos. 4,774,339 and 5,433,896, JP-A Nos. 2001-240761 and 2002-155052, Japanese Patent No. 3614586, Aust. J. Chem, 1965, 11, 1835-1845, and J. H. Boger et al, Heteroatom Chemistry, Vol. 1, No. 5,389 (1990).

More specifically, the methods described in paragraphs [0131] to [0157] of JP-A No. 2008-292970 may be applied to the synthesis of the specific complex in the invention.

The dye used in the dye solution in the invention is not limited to the specific complex, and dyes having other structures may be used. Use of two or more dyes having structures other than specific complexes is also permissible.

When preparing the color curable composition using plural dyes, separate dye solutions may be prepared for the respective dyes, and the dye solutions prepared may be mixed with the pigment dispersion liquid.

When using the specific complex, one specific complex may be used singly, or two or more specific complexes may be used in combination. It is also permissible to use at least one specific complex with at least one dye having a structure other than specific complexes.

The amount of dye contained in the dye solution in the invention varies depending on the molecular weight and molar absorption coefficient thereof, and is preferably from 5% by mass to 100% by mass, more preferably from 15% by mass to 100% by mass, and still more preferably from 50% by mass to 100% by mass, relative to the total amount of the solids contained in the dye solution.

A favorable dispersion stability of the mixed solution formed by mixing with the pigment dispersion liquid is obtained within the above dye content range.

### <Organic Solvent>

An organic solvent to be used in the dye solution may be any organic solvent that dissolves the dye. Considering that the dye solution is mixed with the pigment dispersion liquid described below so as to form a color curable composition, the organic solvent to be used in the dye solution is preferably an organic solvent having a structure similar to that of the organic solvent used in the pigment dispersion liquid, and is more preferably the same organic solvent as the organic solvent used in the pigment dispersion liquid.

Examples of an organic solvent to be used in the dye solution include an ester, an ether, a ketone, and an aromatic hydrocarbon. Examples of the ester include; ethyl acetate; n-butyl acetate; isobutyl acetate; amyl formate; isoamyl acetate; isobutyl acetate; butyl propionate; isopropyl butyrate; ethyl butyrate; butyl butyrate; methyl lactate; ethyl lactate; an alkyl oxyacetate such as a methyl oxyacetate, an ethyl oxyacetate, or a butyl oxyacetate, specific examples of which include methyl methoxyacetate, ethyl methoxyacetate, butyl methoxyacetate, methyl ethoxyacetate, and ethyl ethoxyacetate; an alkyl 3-oxypropionate such as a methyl 3-oxypropionate or an ethyl 3-oxypropionate, specific examples of which include methyl 3-methoxypropionate, ethyl 3-methoxypropionate, methyl 3-ethoxypropionate, and ethyl 3-ethoxypropionate; an alkyl 2-oxypropionate such as a methyl 2-oxypropionate, an ethyl 2-oxypropionate, or a propyl 2-oxypropionate, specific examples of which include methyl 2-methoxypropionate, ethyl 2-methoxypropionate, propyl 2-methoxypropionate, methyl 2-ethoxypropionate, and ethyl 2-ethoxypropionate; a methyl 2-oxy-2-methylpropionate or an ethyl 2-oxy-2-methylpropionate, such as methyl 2-methoxy-2-methylpropionate or ethyl 2-ethoxy-2-methylpropionate; methyl pyruvate; ethyl pyruvate; propyl pyruvate; methyl acetoacetate; ethyl acetoacetate; methyl 2-oxobutanoate; and ethyl 2-oxobutanoate.

Examples of the ether include diethyleneglycol dimethyl ether, tetrahydrofuran, ethyleneglycol monomethyl ether, ethyleneglycol monoethyl ether, methyl cellosolve acetate, ethyl cellosolve acetate, diethyleneglycol monomethyl ether, diethyleneglycol monoethyl ether, diethyleneglycol monobutyl ether, propyleneglycol monomethyl ether, propyleneglycol monomethyl ether acetate, propyleneglycol monoethyl ether acetate, and propyleneglycol monopropyl ether acetate.

Examples of the ketone include methyl ethyl ketone, cyclohexanone, 2-heptanone, and 3-heptanone.

Examples of the aromatic hydrocarbon include toluene and xylene. Of these, the organic solvent is preferably at least one selected from the group consisting of cyclohexanone, propyleneglycol monomethyl ether acetate, propyleneglycol monomethyl ether, and ethyl lactate, from the viewpoints of the solubility of the dye and the coating properties of the color curable composition.

It is preferable to mix two or more organic solvents, from the viewpoints of, for example, the solubility of the dye, the solubility of other optional ingredients added to the dye solution, and coating properties of the color curable composition. The mixture of two or more organic solvents is preferably a mixed solution composed of two or more selected from methyl 3-ethoxypropionate, ethyl 3-ethoxypropionate, ethyl cellosolve acetate, ethyl lactate, diethyleneglycol dimethyl ether, butyl acetate, methyl 3-methoxypropionate, 2-heptanone, cyclohexanone, ethyl carbitol acetate, butyl carbitol acetate, propyleneglycol methyl ether, or propyleneglycol methyl ether acetate.

<Preparation of Dye Solution>

Although the method for preparing the dye solution may be a method in which an organic solvent is added to a dye and agitated, or a method in which a dye powder is added into an organic solvent while agitating the organic solvent. With regard to the manner of adding the dye, although the total volume of the dye may be added at once, the dye is preferably added in installments. When the dye is added in installments, it is preferable to employ a method in which the following process is repeated: adding a dye at an amount corresponding to from one tenth to one half of the total amount of the dye into an organic solvent, visually confirming that the dye is generally dissolved, and then adding the next portion of the dye. In an embodiment, a slurry of the dye is formed, in advance, by using a small amount of organic solvent, and the dye is added in the form of the slurry.

With regard to the method of dissolution, the liquid containing the dye and the organic solvent may be agitated with a rod-shaped object or with a magnetic stirrer. For example, a usual agitator that rotates a propeller-shaped stirring member in a vessel at a constant rate in one rotational direction may be used for dissolution.

The dissolution may be conducted by applying a shearing force by using, for example, a mixer or a dissolver. The liquid may be heated during dissolution, as necessary.

At least one of a radical stabilizing agent, a UV absorber, a thermosetting material, a surfactant, or the like may be added to the dye solution in the invention, as necessary.

The content of organic solvent in the dye solution is preferably such that the total concentration of solids contained in the dye solution is from 5% by mass to 30% by mass, and more preferably from 10% by mass to 20% by mass. A favorable dissolution of the dye can be achieved within the above range.

<Pigment Dispersion Liquid, Pigment>

Next, the process of preparing a pigment dispersion liquid by dispersing at least a pigment using a dispersant is described.

Examples of a pigment that can be used in the pigment dispersion liquid in the invention include various conventional known inorganic and organic pigments. It is preferable to use a pigment having a very small particle size, and the particle diameter is preferably as small as possible, considering that the pigment preferably has a high transparency regardless of whether the pigment is an inorganic pigment or an organic pigment. The pigment has an average primary particle diameter of preferably from 0.01 μm to 0.3 μm, more preferably from 0.01 μm to 0.15 μm, in further consideration of handling properties. A particle diameter within the above range is effective in terms of production of a color filter having high transparency, excellent color characteristics, and high contrast with reduced color unevenness.

The average primary particle diameter is determined as follows. Particles are observed under a SEM (scanning electron microscope) or TEM (transmission electron microscope), and the sizes of 100 particles are measured in an area at which particles do not aggregate. The average value thereof is calculated, and is used as the average primary particle diameter.

Examples of the inorganic pigment include metal compounds such as metal oxides and metal complex salts. Specific examples thereof include oxides of metals such as iron, cobalt, aluminum, cadmium, lead, copper, titanium, magnesium chromium, zinc and antimony, and complex oxides of the above metals.

Examples of the organic pigment include:

C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, and 279;

C. I. Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, and 214;

C. I. Pigment Orange 2, 5, 13, 16, 17:1, 31, 34, 36, 38, 43, 46, 48, 49, 51, 52, 55, 59, 60, 61, 62, 64, 71, and 73;

C. I. Pigment Green 7, 10, 36, 37, and 58;

C. I. Pigment Blue 1, 2, 15, 15:1, 15:2, 15:3, 15:4, 15:6, 16, 22, 60, 64, 66, 79, and 80, and a pigment obtained by replacing a Cl substituent of C. I. Pigment Blue 79 by OH;

C. I. Pigment Violet 1, 19, 23, 27, 32, 37, and 42;

C. I. Pigment Brown 25 and 28; and

C. I. Pigment Black 1.

Of these, preferable examples of pigments that can be used include, but are not limited to, the following:

C. I. Pigment Yellow 11, 24, 108, 109, 110, 138, 139, 150, 151, 154, 167, 180, and 185;

C. I. Pigment Orange 36 and 71;

C. I. Pigment Red 122, 150, 171, 175, 177, 209, 224, 242, 254, 255, and 264;

C. I. Pigment Violet 19, 23, and 32;

C. I. Pigment Blue 15:1, 15:3, 15:6, 16, 22, 60, and 66;

C. I. Pigment Green 7, 36, 37, and 58;

C. I. Pigment Black 1.

Fining of Pigment

As necessary, an organic pigment composed of fine and uniformized particles may be used as a pigment to be used in the pigment dispersion liquid in the invention. The fining of the pigment may be achieved through the processes of preparing a high-viscosity liquid composition from at least a pigment, a water-soluble organic solvent and a water-soluble inorganic salt, and grinding the pigment by applying a stress using, for example, a wet-crushing apparatus.

Examples of the water-soluble organic solvent used in the process of fining the pigment include methanol, ethanol, isopropanol, n-propanol, isobutanol, n-butanol, ethyleneglycol, diethyleneglycol, diethyleneglycol monomethyl ether, diethyleneglycol monoethyl ether, diethyleneglycol monobutyl ether, propyleneglycol, and propyleneglycol monomethyl ether acetate.

Other organic solvents that have low water-solubility or no water-solubility may be used as long as the amount thereof is so small that the solvents are adsorbed to the pigment and do not flow into waste water; examples thereof include benzene, toluene, xylene, ethylbenzene, chlorobenzene, nitrobenzene, aniline, pyridine, quinoline, tetrahydrofuran, dioxane, ethyl acetate, isopropyl acetate, butyl acetate, hexane, heptane, octane, nonane, decane, undecane, dodecane, cyclohexane, methylcyclohexane, a halogenated hydrocarbon, acetone, methyl ethyl ketone, methyl isobutyl ketone, cyclohexanone, dimethylformamide, dimethylsulfoxide and N-methylpyrrolidone.

For the process of fining the pigment, one solvent may be used singly, or two or more solvents may be mixed and used if necessary.

Examples of the water-soluble inorganic salt used in the process of fining the pigment include sodium chloride, potassium chloride, calcium chloride, barium chloride and sodium sulfate.

The amount, in terms of weight, of the water-soluble inorganic salt used in the fining process is from 1 to 50 times that of the pigment. Although a greater amount produces a stronger grinding effect, the amount of the water-soluble inorganic salt in terms of weight is more preferably from 1 to 10 times that of the pigment, from the viewpoint of favorable productivity. The moisture content of the water-soluble inorganic salt used in the fining process is preferably 1% by weight or lower.

The amount of the water-soluble organic solvent used in the fining process is preferably from 50 parts by mass to 300 parts by mass, more preferably from 100 parts by mass to 200 parts by mass, relative to 100 parts by mass of the pigment.

There are no particular limitations on the operation conditions of the wet-crushing apparatus in the process of fining the pigment. In order to perform effective grinding with a grinding medium, the operation conditions when the apparatus is a kneader are such that the rotation number of the blade in the apparatus is preferably from 10 rpm to 200 rpm, and the ratio between the rotations of the two axes is preferably relatively high due to greater grinding effects achieved thereby. The total operation time, including dry crushing time, is preferably from 1 hour to 8 hours, and the internal temperature of the apparatus is preferably from 50° C. to 150° C. It is preferable that the water-soluble inorganic salt as a crushing medium has a crushed particle size of from 5 μm to 50 μm, has a sharp particle diameter distribution, and has a spherical shape.

The amount of pigment contained in the pigment dispersion liquid in the invention is preferably from 10% by mass to 60% by mass, more preferably from 15% by mass to 50% by mass, relative to the total amount (by mass) of solids contained in the pigment dispersion liquid. A pigment amount within the above range is effective in terms of ensuring sufficient color density and superior color characteristics.

The pigment dispersion liquid in the invention includes at least one dispersant. The inclusion of the dispersant improves pigment dispersibility.

The dispersant may be appropriately selected from, for example, known pigment dispersants and surfactants. In the invention, the dispersant is preferably a polymeric dispersant since dispersion stability of the pigment is obtained by the use of the polymeric dispersant.

Many types of compound may be used as dispersants. Examples thereof include: cationic surfactants such as an organosiloxane polymer KP341 (tradename: manufactured by Shin-Etsu Chemical Co., Ltd.) and (meth)acrylic (co)polymers POLYFLOW No. 75, No. 90 and No. 95 (tradenames: manufactured by KYOEISHA CHEMICAL Co., Ltd.) and W001 (tradename, manufactured by Yusho Co., Ltd.); nonionic surfactants such as polyoxyethylene lauryl ether, polyoxyethylene stearyl ether, polyoxyethylene oleyl ether, polyoxyethylene octyl phenyl ether, polyoxyethylene nonyl phenyl ether, polyethyleneglycol dilaurate, polyethyleneglycol distearate and sorbitan fatty acid ester; anionic surfactants such as W004, W005 and W017 (all of which are tradenames, manufactured by Yusho Co., Ltd.); polymeric dispersants such as EFKA-46, EFKA-47, EFKA-47EA, EFKA POLYMER 100, EFKA POLYMER 400, EFKA POLYMER 401 and EFKA POLYMER 450 (all of which are tradenames, manufactured by BASF Japan Ltd.) and DISPERSE AID 6, DISPERSE AID 8, DISPERSE AID 15 and DISPERSE AID 9100 (all of which are tradenames, manufactured by SAN NOPCO LIMITED); various SOLSPERSE dispersants such as SOLSPERSE 3000, 5000, 9000, 12000, 13240, 13940, 17000, 24000, 26000 and 28000 (all of which are tradenames, manufactured by Lubrizol Japan Ltd.); and ADEKA PLURONIC L31, F38, L42, L44, L61, L64, F68, L72, P95, F77, P84, F87, P94, L101, P103, F108, L121 and P-123 (all of which are tradenames, manufactured by ADEKA Corporation); IONET S-20 (tradename, manufactured by Sanyou Chemical Industries Co., Ltd.); and DISPERBYK 101, 103, 106, 108, 109, 111, 112, 116, 130, 140, 142, 162, 163, 164, 166, 167, 170, 171, 174, 176, 180, 182, 2000, 2001, 2050 and 2150 (all of which are tradenames, manufactured by BYK Japan KK). Further examples include an oligomer or polymer having a polar group at a molecular terminal or at a side chain, such as an acrylic copolymer.

The amount of dispersant contained in the pigment dispersion liquid is preferably from 1 to 100 parts by mass, and more preferably from 3 to 70 parts by mass, relative to 100 parts by mass of the pigment.

It is also preferable to use two or more dispersants together. For example, it is preferable to use at least one polymeric dispersant and at least one low-molecular dispersant.

In the invention, various compounds other than the pigment, dispersant and organic solvent may be added when preparing a pigment dispersion liquid. Optional ingredients that are useful for the preparation of the pigment dispersion liquid are described below.

Pigment Derivative

A pigment derivative may be added to the pigment dispersion liquid in the invention, as necessary. Use of a pigment derivative is effective in terms of obtaining an excellent color filter having high contrast and being substantially free of color unevenness. This is because the pigment derivative to which a polar group or a moiety having affinity for the dispersant has been introduced is adsorbed on the surface of the pigment, and serves as an adsorption site for the dispersant, as a result of which the pigment can be dispersed as fine particles in the color curable composition, and reaggregation thereof can be prevented.

A known pigment derivative having an organic pigment as a parent skeleton may be used as the pigment derivative, as appropriate. Examples of the organic pigment include quinacridone pigments, phthalocyanine pigments, azo pigments, quinophthalone pigments, isoindoline pigments, isoindolinone pigments, quinoline pigments, diketopyrrolopyrrole pigments and benzimidazolone pigments. Examples further include pale-yellow aromatic polycyclic compounds, such as naphthalene pigments, anthraquinone pigments, triazine pigments and quinoline pigments, that are not generally called colorants.

Examples of usable colorant derivatives include those described in, for example, JP-A Nos. 11-49974, 11-189732, 10-245501, 2006-265528, 8-295810, 11-199796, 2005-234478, 2003-240938, and 2001-356210.

The amount of the pigment derivative contained in the pigment dispersion liquid in the invention is preferably from 0 to 30 parts by mass, more preferably from 3 to 20 parts by mass, relative to 100 parts by mass of pigment. When the content of pigment derivative is within the above range, dispersion can be performed well while maintaining viscosity at a low level, the dispersion stability after dispersion can be improved, high transparency and superior color characteristics are obtained, and a color filter obtained has superior color characteristics.

<Preparation of Pigment Dispersion Liquid>

With regard to the method for preparing the pigment dispersion liquid, for example, a pigment, a dispersant, and an organic solvent may be mixed in advance and subjected to pre-dispersion, and then the pre-dispersed mixture may be finely dispersed using, for example, a bead disperser in which zirconia beads or the like are used, as a result of which the pigment dispersion liquid is obtained.

The finely dispersing may be performed using mainly a vertical or horizontal sand grinder mill, a pin mill, a slit mill, a ultrasonic disperser or the like, and using beads having a particle diameter of from 0.01 mm to 1 mm and made of glass, zirconia, or the like, thereby obtaining the pigment dispersion liquid.

The pre-dispersion performed before bead dispersion may be conducted on a mixture containing a pigment, a dispersant, and an organic solvent and optionally further containing at least one of a pigment derivative or an alkali-soluble resin, by using a two-roll mill, a three-roll mill, a ball mill, a trommel, a disper, a kneader, a cokneader, a homogenizer, a blender or a uniaxial or biaxial extruder, whereby a kneading and dispersing treatment is conducted while applying strong shear force.

The dispersing time of the bead dispersion is preferably from about 3 hours to about 6 hours. Although the addition of the pigment derivative may be performed at any stage during the preparation of the pigment dispersion liquid, the addition of the pigment derivative is preferably performed during the process of fining the pigment and/or at the time of the finely dispersing.

The specifics of the kneading and dispersing are described in, for example, T. C. Patton “Paint Flow and Pigment Dispersion” (John Wiley and Sons Inc., 1964).

Examples of an organic solvent that can be used in the pigment dispersion liquid include the organic solvents described in the section (explanation) of the dye solution.

<Preparation of Color Curable Composition>

The pigment dispersion liquid thus prepared, and the above-described dye solution are mixed, and other optional ingredients such as a polymerization initiator and a polymerizable compound are added thereto, as a result of which a color curable composition is obtained.

With regard to the method for preparing the color curable composition, the dye solution may be added to the pigment dispersion liquid, or, alternatively, the pigment dispersion liquid may be added to the dye solution. Further, other optional ingredients such as an organic solvent, a polymerization initiator, or a polymerizable compound may be added as necessary, and the resultant is agitated by an agitator which may be the agitator described in the section (explanation) of the preparation of the dye solution, as a result of which the color curable composition is obtained.

The color curable composition thus prepared may be filtered through a filter having a pore diameter of preferably from 0.01 μm to 3.0 μm, more preferably from 0.05 μm to 0.5 μm, and still more preferably from 0.2 μm to 0.5 μm, and may thereafter be used. The material of the filter is preferably polyethylene, polypropylene, or nylon.

The amount of solids contained in the color curable composition according to the invention is preferably from 13% by mass to 20% by mass, and more preferably from 15% by mass to 20% by mass, relative to the entire color curable composition. A favorable control of the layer thickness is achieved within the above range.

The amount, in terms of pigment amount, of the pigment dispersion liquid contained in the color curable composition according to the invention is preferably in the range of from 10% by mass to 60% by mass, and more preferably from 20% by mass to 58% by mass, relative to the amount of solids contained in the color curable composition. The amount, in terms of dye amount, of the dye solution contained in the color curable composition is preferably from 10% by mass to 60% by mass, and more preferably from 15% by mass to 40% by mass, relative to the amount of solids contained in the color curable composition.

As a result of the incorporation of the pigment dispersion and the dye solution within the above blending amount ranges, a color curable composition having superior dispersion properties and superior dispersion stability, and capable of forming a color filter that has high contrast and substantially no color unevenness and that has sufficient hue even with a small layer thickness, is obtained.

Mixing of Pigment and Dye

Preferable combinations of the pigment contained in the pigment dispersion liquid used for the preparation of a color curable composition and the dye contained in the dye solution are described below.

Various combinations of the pigment and the dye allow achievement of desired hues and color purities. Specific examples of the combinations are described below.

Red Color

A preferable combination is a combination of any of an anthraquinone pigment, a perylene pigment, a diketopyrrolopyrrole pigment, a disazo yellow pigment, an isoindoline yellow pigment, or a quinophthalone yellow pigment, with any of an aniline azo dye, a thiazole azo dye, an anthraquinone dye, an anthrapyridone dye, an azine dye, a quinophthalone dye, a pyrazolotriazole dye, a pyridone azo dye, or a methine dye. A more preferable combination is a combination of at least one of C.I. Pigment Red 177, C.I. Pigment Red 155, C.I. Pigment Red 224, or C.I. Pigment Red 254 with at least one of a quinophthalone dye, a pyrazolotriazole dye, a pyridone azo dye, or a methine dye, or a combination of at least one of C.I. Pigment Yellow 83, C.I. Pigment Yellow 139, or C.I. Pigment Red 177 with at least one of an aniline azo dye, a thiazole azo dye, an anthraquinone dye, or an anthrapyridone dye.

The mass ratio of pigment to dye in the color curable composition (pigment:dye) is preferably in the range of from 100:20 to 100:500, and more preferably in the range of from 100:30 to 100:100. Within the above range, light transmittance within a wavelength range of from 400 nm to 500 nm is maintained low, color purity can be improved, and sufficient coloring power is exerted.

Green Color

A preferable combination is a combination of any of a halogenated phthalocyanine pigment, a disazo yellow pigment, a quinophthalone yellow pigment, an azomethine yellow pigment, or an isoindoline yellow pigment with any of a phthalocyanine dye, a quinophthalone dye, a pyrazolotriazole dye, a pyridone azo dye, or a methine dye.

A more preferable combination is a combination of at least one of C.I. Pigment Green 7, C.I. Pigment Green 36, C.I. Pigment Green 37, or C.I. Pigment Green 58 with at least one of a quinophthalone dye, a pyrazolotriazole dye, a pyridone azo dye, or a methine dye, or a combination of at least one of C.I. Pigment Yellow 83, C.I. Pigment Yellow 138, C.I. Pigment Yellow 139, C.I. Pigment Yellow 150, C.I. Pigment Yellow 180, or C.I. Pigment Yellow 185 with at least one of a quinophthalone dye, a pyrazolotriazole dye, a pyridone azo dye, or a methine dye. A particularly preferable combination is a combination of C.I. Pigment Green 36 or C.I. Pigment Green 58, with at least one of a quinophthalone dye, a pyrazolotriazole dye, a pyridone azo dye, or a methine dye.

The mass ratio of pigment to dye in the color curable composition (pigment:dye) is preferably in the range of from 100:20 to 100:500, and more preferably from in the range of 100:30 to 100:100. Within the above range, light transmittance within wavelength ranges of from 400 nm to 450 nm and from 650 nm to 700 nm is maintained low, color purity can be improved, and sufficient coloring power is exerted.

Blue Color

A preferable combination is a combination of at least one of a phthalocyanine pigment or a dioxazine purple pigment with at least one of a phthalocyanine dye or a pyrromethene dye. A particularly preferable combination is a mixture of C.I. Pigment Blue 15:6 or C.I. Pigment Violet 23, with a pyrromethene dye.

The mass ratio of pigment to dye in the color curable composition (pigment:dye) is preferably in the range of from 100:20 to 100:500, and more preferably in the range of from 100:30 to 100:100. Within the above range, light transmittance within wavelength range of from 500 nm to 700 nm is maintained low, color purity can be improved, and sufficient coloring power is exerted.

A particularly preferable combination in the invention is a combination of a dye that is the specific complex containing a compound represented by Formula (I) described above and a metal atom or metal compound, with a phthalocyanine pigment. This combination allows the effects of the invention to be exerted remarkably.

Phthalocyanine Pigment

The phthalocyanine pigment is not particularly limited as long as the pigment has a phthalocyanine skeleton. The central metal contained in the phthalocyanine pigment is not particularly limited as long as a phthalocyanine skeleton can be formed with the metal. Preferable examples of the central metal include magnesium, titanium, iron, cobalt, nickel, copper, zinc, and aluminum.

Specific examples of the phthalocyanine pigment include C.I. Pigment Blue 15, C.I. Pigment Blue 15:1, C.I. Pigment Blue 15:2, C.I. Pigment Blue 15:3, C.I. Pigment Blue 15:4, C.I. Pigment Blue 15:5, C.I. Pigment Blue 15:6, C.I. Pigment Blue 16, C.I. Pigment Blue 17:1, C.I. Pigment Blue 75, C.I. Pigment Blue 79, C.I. Pigment Green 7, C.I. Pigment Green 36, C.I. Pigment Green 37, chloroaluminum phthalocyanine, hydroxyaluminum phthalocyanine, aluminum phthalocyanine oxide, and zinc phthalocyanine. Of these, C.I. Pigment Blue 15, C.I. Pigment Blue 15:6, Pigment Blue 15:1, and C.I. Pigment Blue 15:2 are preferable in terms of light fastness and coloring powers, and C.I. Pigment Blue 15:6 is particularly preferable.

The amount of phthalocyanine pigment contained in the color curable composition is preferably from 10% by mass to 60% by mass, more preferably from 20% by mass to 60% by mass, and most preferably from 35% by mass to 50% by mass, relative to the total amount of solids contained in the color curable composition.

In the color curable composition, the ratio of the amount of phthalocyanine pigment to the amount of specific complex (phthalocyanine pigment:specific complex) is preferably from 100:20 to 100:500, more preferably from 100:25 to 100:300, and still more preferably from 100:30 to 100:100.

In the following, preferable ingredients that may be contained in the color curable composition according to the invention are described. These ingredients are preferably added during the process of preparing a color curable composition by mixing the dye solution and the pigment dispersion liquid. However, it is also permissible to add the ingredients during the preparation of the pigment dispersion liquid and/or the preparation of the dye solution.

<Polymerizable Compound>

The color curable composition according to the invention preferably includes a polymerizable compound. The polymerizable compound may be an addition-polymerizable compound having at least one ethylenic unsaturated double bond, which may be selected from compounds each having at least one ethylenic unsaturated bond at terminal(s), preferably two or more ethylenic unsaturated bonds at terminals. Such a class of compounds is widely known in the relevant industrial field, and such compounds may be used in the invention without particular limitations. Such compounds may be in the chemical form of a monomer or a prepolymer, specifically a dimer, a trimer or an oligomer, or a mixture thereof or a (co)polymer thereof.

Examples of monomers and (co)polymers thereof include an unsaturated carboxylic acid (such as acrylic acid, methacrylic acid, itaconic acid, crotonic acid, isocrotonic acid, or maleic acid), an ester thereof, an amide thereof, and a (co)polymer thereof. Preferable examples thereof include: an ester of an unsaturated carboxylic acid and an aliphatic polyhydric alcohol compound, an amide of an unsaturated carboxylic acid and an aliphatic polyamine compound, and (co)polymers thereof; an addition reaction product of an unsaturated carboxylic acid ester or amide having a nucleophilic substituent (such as a hydroxyl group, an amino group, or a mercapto group), with a monofunctional or polyfunctional isocyanate or epoxy compound, and a dehydration condensation reaction product of such an ester or amide with a monofunctional or polyfunctional carboxylic acid; an addition reaction product of an unsaturated carboxylic acid ester or amide having an electrophilic substituent (such as an isocyanate group, or an epoxy group), with a monofunctional or polyfunctional alcohol, amine, or thiol; a substitution reaction product of an unsaturated carboxylic acid ester or amide having a halogen group or a leaving substituent (such as a tosyloxy group), with a monofunctional or polyfunctional alcohol, amine, or thiol; and a compound obtained by replacing an unsaturated carboxylic acid in the above examples by an unsaturated phosphonic acid, styrene, vinyl ether, or the like.

Examples of the ester of an aliphatic polyhydric alcohol compound and an unsaturated carboxylic acid as a monomer include: an acrylic ester such as ethyleneglycol diacrylate, triethyleneglycol diacrylate, 1,3-butanediol diacrylate, tetramethyleneglycol diacrylate, propyleneglycol diacrylate, neopentylglycol diacrylate, trimethylolpropane triacrylate, trimethylolpropane tri(acryloyloxypropyl)ether, trimethylolethane triacrylate, hexanediol diacrylate, 1,4-cyclohexanediol diacrylate, tetraethyleneglycol diacrylate, pentaerythritol diacrylate, pentaerythritol triacrylate, pentaerythritol tetraacrylate, dipentaerythritol diacrylate, dipentaerythritol hexaacrylate, sorbitol triacrylate, sorbitol tetraacrylate, sorbitol pentaacrylate, sorbitol hexaacrylate, tri(acryloyloxyethyl)isocyanurate, a polyester acrylate oligomer, or an EO-modified isocyanuric acid triacrylate.

Examples of the ester of an aliphatic polyhydric alcohol compound and an unsaturated carboxylic acid as a monomer also include a methacrylic ester such as tetramethyleneglycol dimethacrylate, triethyleneglycol dimethacrylate, neopentylglycol dimethacrylate, trimethylolpropane trimethacrylate, trimethylolethane trimethacrylate, ethyleneglycol dimethacrylate, 1,3-butanediol dimethacrylate, hexanediol dimethacrylate, pentaerythritol dimethacrylate, pentaerythritol trimethacrylate, pentaerythritol tetramethacrylate, dipentaerythritol dimethacrylate, dipentaerythritol hexamethacrylate, sorbitol trimethacrylate, sorbitol tetramethacrylate, bis[p-(3-methacryloxy-2-hydroxypropoxy)phenyl]dimethylmethane, or bis[p-(methacryloxyethoxy)phenyl]dimethylmethane.

Examples of the ester of an aliphatic polyhydric alcohol compound and an unsaturated carboxylic acid as a monomer also include: an itaconic ester such as ethyleneglycol diitaconate, propyleneglycol diitaconate, 1,3-butanediol diitaconate, 1,4-butanediol diitaconate, tetramethyleneglycol diitaconate, pentaerythritol diitaconate, or sorbitol tetraitaconate; a crotonic ester such as ethyleneglycol dicrotonate, tetramethyleneglycol dicrotonate, pentaerythritol dicrotonate, or sorbitol tetradicrotonate; an isocrotonic ester such as ethyleneglycol diisocrotonate, pentaerythritol diisocrotonate, or sorbitol tetraisocrotonate; and a maleic ester such as ethyleneglycol dimaleate, triethyleneglycol dimaleate, pentaerythritol dimaleate, or sorbitol tetramaleate.

Examples of other esters include the aliphatic alcohol esters described in Japanese Patent Application Publication (JP-B) Nos. 51-47334 and JP-A No. 57-196231, the aromatic skeleton-containing compounds described in JP-A Nos. 59-5240, 59-5241 and 02-226149, and the amino group-containing compounds described in JP-A No. 01-165613. The ester monomers described above may be used as a mixture of two or more thereof.

Examples of the amide of an aliphatic polyamine compound and an unsaturated carboxylic acid as a monomer include methylenebis-acrylamide, methylenebis-methacrylamide, 1,6-hexamethylenebis-acrylamide, 1,6-hexamethylenebis-methacrylamide, diethylenetriaminetrisacrylamide, xylylenebisacrylamide, and xylylenebismethacrylamide.

Examples of other preferred amide monomers include the compounds having a cyclohexylene structure described in JP-B No. 54-21726.

Addition-polymerizable urethane compounds produced by an addition reaction of isocyanate with a hydroxyl group are also preferred, examples of which include the vinyl urethane compounds described in JP-B No. 48-41708, which have two or more polymerizable vinyl groups within one molecule and are produced by adding a hydroxyl group-containing vinyl monomer represented by Formula (A) below to a polyisocyanate compound having two or more isocyanate groups within a molecule.

CH₂═C(R)COOCH₂CH(R′)OH (A)

In Formula (A), R and R′ each independently represent H or CH₃.

Preferable examples of the polymerizable compound also include an ethylenic unsaturated compound having an acid group. The ethylenic unsaturated compound having an acid group can be obtained, for example, by a method in which a portion of the hydroxy groups of the polyfunctional alcohol are (meth)acrylated, and acid anhydrides are added to the remaining groups to form carboxy groups. Specific examples thereof include commercially available products such as TO-756 (tradename, manufactured by TOAGOSEI Co., Ltd.), which is a trifunctional acrylate having a carboxy group, and TO-1382 (tradename, manufactured by TOAGOSEI Co., Ltd.), which is a pentafunctional acrylate having a carboxy group.

Details of how to use the polymerizable compounds, such as what structure should be used, whether they should be used alone or in combination, or what amount should be added, may be freely determined depending on the final performance design of the color curable composition. For example, they may be selected from the following viewpoints.

In view of sensitivity, a structure having a higher content of the unsaturated groups per molecule is preferable, and bifunctional or higher functional structures are preferred in many cases. In order to increase the strength of the color cured film, tri- or higher-functional structures are preferred. A method of using a combination of compounds having different numbers of functional groups and/or different types of polymerizable groups (for example, compounds selected from an acrylic ester, a methacrylic ester, a styrene compound, or a vinyl ether compound) is also effective for controlling both of sensitivity and strength.

How to select and use the polymerizable compound is also an important factor for the compatibility with or dispersibility to other components contained in the curable composition (such as a photopolymerization initiator, a pigment, a dye, and a binder polymer). For example, in some cases, the compatibility may be improved by using a low-purity compound or by using a combination of two or more compounds. A particular structure may also be selected in order to improve adhesion to a hard surface of a support or the like.

The amount of polymerizable compound contained in the color curable composition (the total amount of polymerizable compounds If there are two or more polymerizable compounds) relative to the total amount of solids contained in the color curable composition is not particularly limited, and is preferably from 10% by mass to 80% by mass, more preferably from 15% by mass to 75% by mass, and still more preferably from 20% by mass to 60% by mass, from the viewpoint of more effectively exerting the effects of the invention.

<Photopolymerization Initiator>

The color curable composition preferably includes a photopolymerization initiator.

The photopolymerization initiator is not particularly limited as long as it is capable of polymerizing the polymerizable compound described above, and is preferably selected in consideration of, for example, properties, initiation efficiency, absorption wavelength, availability, and cost.

Examples of the photopolymerization initiator include: at least one active halogen compound selected from a halomethyl oxadiazole compound or a halomethyl-s-triazine compound; 3-aryl-substituted coumarin compounds; lophine dimer, benzophenone compounds, acetophenone compounds and derivatives thereof; cyclopentadiene-benzene-iron complexes and salts thereof; and oxime compounds. Specific examples of the photopolymerization initiator include those described in paragraphs [0070] to [0077] of JP-A No. 2004-295116. Among them, oxime compounds are preferable due to rapidness of a polymerization reaction initiated thereby.

The oxime compounds (hereinafter referred to as “oxime photopolymerization initiators” in some cases) are not particularly limited, and examples thereof include the oxime compounds described in JP-A No. 2000-80068, WO02/100903A1, and JP-A No. 2001-233842.

Specific examples thereof include, but are not limited to, 2-(O-benzoyloxime)-1-[4-(phenylthio)phenyl]-1,2-butanedione, 2-(O-benzoyloxime)-1-[4-(phenylthio)phenyl]-1,2-pentanedione, 2-(O-benzoyloxime)-1-[4-(phenylthio)phenyl]-1,2-hexanedione, 2-(O-benzoyloxime)-1-[4-(phenylthio)phenyl]-1,2-heptanedione, 2-(O-benzoyloxime)-1-[4-(phenylthio)phenyl]-1,2-octanedione, 2-(O-benzoyloxime)-1-[4-(methylphenylthio)phenyl]-1,2-butanedione, 2-(O-benzoyloxime)-1-[4-(ethylphenylthio)phenyl]-1,2-butanedione, 2-(O-benzoyloxime)-1-[4-(butylphenylthio)phenyl]-1,2-butanedione, 1-(O-acetyloxime)-1-[9-ethyl-6-(2-methylbenzoyl)-9H-carbazol-3-yl]ethanone, 1-(O-acetyloxime)-1-[9-methyl-6-(2-methylbenzoyl)-9H-carbazol-3-yl]ethanone, 1-(O-acetyloxime)-1-[9-propyl-6-(2-methylbenzoyl)-9H-carbazol-3-yl]ethanone, 1-(O-acetyloxime)-1-[9-ethyl-6-(2-ethylbenzoyl)-9H-carbazol-3-yl]ethanone, and 1-(O-acetyloxime)-1-[9-ethyl-6-(2-butylbenzoyl)-9H-carbazol-3-yl]ethanone

Of these, oxime-O-acyl compounds, such as 2-(O-benzoyloxime)-1-[4-(phenylthio)phenyl]-1,2-octanedione and 1-(O-acetyloxime)-1-[9-ethyl-6-(2-methylbenzoyl)-9H-carbazol-3-yl]ethanone, are particularly preferable in terms of capability of providing a pattern having excellent shape (in the case of solid-state image pick-up devices, rectangularity of the pattern) with a lower exposure amount. Specific examples thereof include CGI-124 and CGI-242 (tradenames) manufactured by BASF Japan Ltd.

In the invention, the oxime compound is more preferably a compound represented by the following Formulae (1) and (2), from the viewpoints of sensitivity, temporal stability, and coloring at the time of post-heating (post-baking).

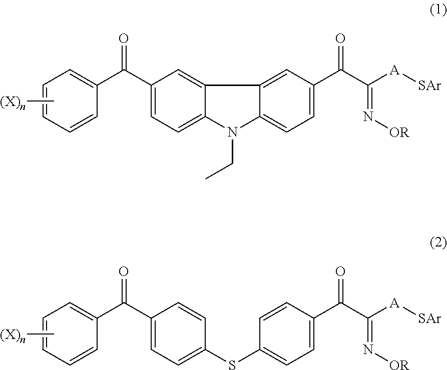

In Formulae (1) and (2) above, R and X each independently represent a monovalent substituent, A represents a divalent organic group, Ar represents an aryl group, and n represents an integer of from 1 to 5.

R in the above Formulas (1) and (2) preferably represents an acyl group from the viewpoint of improving sensitivity. Specifically, an acetyl group, a propionyl group, a benzoyl group, and a toluoyl group are preferable.

In Formulas (1) and (2), A preferably represents an unsubstituted alkylene group, an alkylene group substituted by an alkyl group (such as by a methyl group, an ethyl group, a tert-butyl group, or a dodecyl group), an alkylene group substituted by an alkenyl group (such as a vinyl group or an allyl group), or an alkylene group substituted by an aryl group (such as a phenyl group, a p-tolyl group, a xylyl group, a cumenyl group, a naphthyl group, an anthryl group, a phenanthryl group, or a styryl group), from the viewpoints of heightening sensitivity and suppressing coloration over time when heated.

In Formulae (1) and (2), Ar preferably represents a substituted or unsubstituted phenyl group from the viewpoints of heightening sensitivity and suppressing coloration over time when heated. When Ar represents a substituted phenyl group, Ar preferably has, as a substituent, a halogen group such as a fluorine atom, a chlorine atom, a bromine atom, or an iodine atom.

In Formulae (1) and (2), X preferably represents an alkyl group that may have a substituent, an aryl group that may have a substituent, an alkenyl group that may have a substituent, an alkynyl group that may have a substituent, an alkoxy group that may have a substituent, an aryloxy group that may have a substituent, an alkylthioxy group that may have a substituent, an arylthioxy group that may have a substituent, or an amino group that may have a substituent.

In Formulae (1) and (2), n preferably represents an integer of from 1 to 2.

Specific examples of compounds represented by Formulae (1) and (2) include, but are not limited to, those shown below.

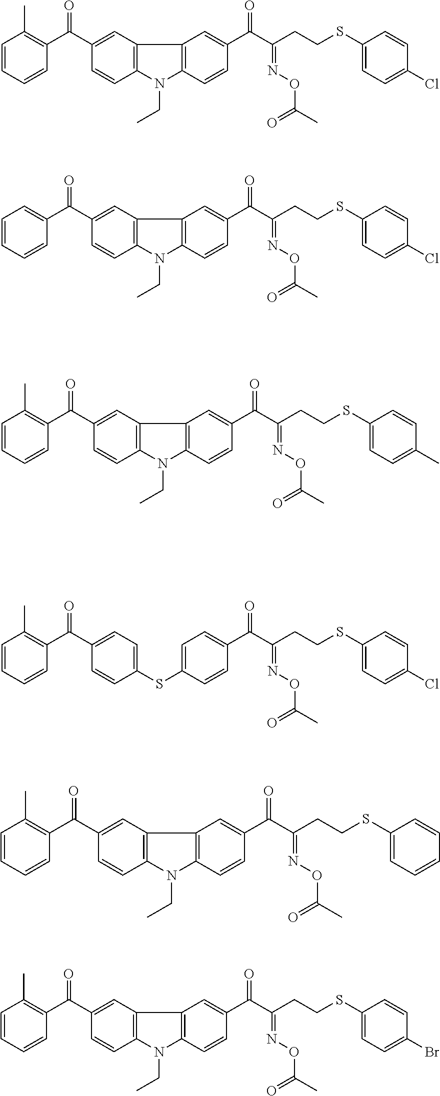

The color curable composition according to the invention may include a known photopolymerization initiator other than the above-described photopolymerization initiators, such as those described in paragraph [0079] of JP-A No. 2004-295116.

The color curable composition may include a single photopolymerization initiator, or include two or more photopolymerization initiators in combination.

The amount of photopolymerization initiator contained in the color curable composition (the total content of photopolymerization initiators if the color curable composition includes two or more photopolymerization initiators) is preferably from 3% by mass to 20% by mass, more preferably from 4% by mass to 19% by mass, and still more preferably from 5% by mass to 18% by mass, relative to the total amount of solids contained in the color curable composition, from the viewpoint of more effectively exerting the effects of the invention.

<Organic Solvent>

The color curable composition according to the invention includes an organic solvent.

The organic solvent is basically not limited as long as it is capable of providing satisfactory dissolution of the ingredients to be used with the organic solvent and imparting satisfactory coating properties to a color curable composition prepared using the organic solvent. The organic solvent is preferably selected in consideration of, particularly, solubility of binder, coating properties, and safety.

Specific examples of the organic solvent include the organic solvents described in the section (explanation) of the dye solution, and examples of preferable compounds are the same as the examples of preferable compounds described in the section (explanation) of the dye solution.

The content of organic solvent contained in the color curable composition is preferably such that the total concentration of solids in the composition is from 10% by mass to 80% by mass, and is more preferably such that the total concentration of solids in the composition is from 15% by mass to 60% by mass.

<Other Components>

As long as the effects of the invention are not impaired, the color curable composition according to the invention may include, in addition to the components described above, another component such as an alkali-soluble binder or a crosslinking agent.

Alkali-Soluble Binder

The alkali-soluble binder has alkali-solubility, and is not particularly limited in other respects. The alkali-soluble binder may be selected from the viewpoints of preferably, heat resistance, developability, availability, and the like.

The alkali-soluble binder is preferably a linear organic high-molecular polymer that is soluble in an organic solvent and that allows development with a weakly-alkaline aqueous solution. The linear organic high-molecular polymer may be a polymer having a carboxylic acid at a side chain, examples of which include a methacrylic acid copolymer, an acrylic acid copolymer, an itaconic acid copolymer, a crotonic acid copolymer, a maleic acid copolymer, and a partially-esterified maleic acid copolymer, such as those described in JP-A No. 59-44615, JP-B No. 54-34327, JP-B No. 58-12577, JP-B No. 54-25957, JP-A No. 59-53836, and JP-A No. 59-71048. Acidic cellulose derivatives having a carboxylic acid at a side chain are also useful.

Other examples of alkali-soluble binders usable in the invention include: an acid anhydride adduct of a polymer having a hydroxyl group, a polyhydroxystyrene resin, a polysiloxane resin, poly(2-hydroxyethyl (meth)acrylate), polyvinylpyrrolidone, polyethylene oxide), and poly(vinyl alcohol). The linear organic polymer high-molecular polymer may be a copolymer formed from monomers including a hydrophilic monomer. Examples of the hydrophilic monomer include an alkoxyalkyl (meth)acrylate, a hydroxyalkyl (meth)acrylate, glycerol (meth)acrylate, (meth)acrylamide, N-methylol acrylamide, a secondary or tertiary alkyl acrylamide, a dialkylaminoalkyl (meth)acrylate, morpholine (meth)acrylate, N-vinylpyrrolidone, N-vinylcaprolactam, vinylimidazole, vinyltriazole, methyl (meth)acrylate, ethyl (meth)acrylate, branched or linear propyl (meth)acrylate, branched or linear butyl (meth)acrylate, and phenoxyhydroxypropyl (meth)acrylate. Further examples of useful hydrophilic monomers include a monomer containing at least one of a tetrahydrofurfuryl group, a phosphoric acid group, a phosphoric ester group, a quaternary ammonium salt group, an ethyleneoxy chain, a propyleneoxy chain, a sulfonic acid group, a group derived from a sulfonic acid salt, or a morpholinoethyl group.

The alkali-soluble binder may have a polymerizable group at a side chain so as to increase the crosslinking efficiency. Therefore, it is useful to use an alkali-soluble binder polymer having, for example, an allyl group, a (meth)acrylic group, or an allyloxyalkyl group at a side chain. Examples of the polymer having a polymerizable group include KS RESIST-106 (tradename, manufactured by OSAKA ORGANIC CHEMISTRY INDUSTRY LTD.) and CYCLOMER P (tradename) series products (manufactured by DAICEL CHEMICAL INDUSTRIES LTD.), which are commercially available products. An alcohol-soluble NYLON (tradename) or a polyether of 2,2-bis-(4-hydroxyphenyl)-propane and epichlorohydrin is useful in terms of increasing the strength of a cured film.

Among the various alkali-soluble binders described above, a polyhydroxystyrene resin, a polysiloxane resin, an acrylic resin, an acrylamide resin, and an acryl/acrylamide copolymer resin are preferable from the viewpoint of heat resistance, and an acrylic resin, an acrylamide resin, and an acryl/acrylamide copolymer resin are preferable from the viewpoint of developability control.

Preferable examples of the acrylic resin include: a copolymer formed from monomers selected from benzyl (meth)acrylate, (meth)acrylic acid, hydroxyethyl (meth)acrylate, (meth)acrylamide, or the like; and DIANAL NR (tradename) series products (manufactured by MITSUBISHI RAYON CO. LTD.), VISCOAT R-264 and KS RESIST-106 (tradenames, manufactured by OSAKA ORGANIC CHEMISTRY INDUSTRY LTD.), CYCLOMER P (tradename) series products and PLACCEL CF200 (tradename) series products (manufactured by DAICEL CHEMICAL INDUSTRIES LTD.), and EBECRYL 3800 (tradename, manufactured by DAICEL-CYTEC Company LTD), which are commercially available products.

The alkali-soluble binder is preferably a polymer having a weight average molecular weight (in teams of a polystyrene-equivalent value as measured by a GPC method) of from 1,000 to 2×10⁵, more preferably from 2,000 to 1×10⁵, and still more preferably from 5,000 to 5×10⁴, from the viewpoints of, for example, developability and liquid viscosity.

Crosslinking Agent

The color curable composition according to the invention may optionally include a crosslinking agent, which further increases the hardness of a color cured film formed by curing of the color curable composition.

The crosslinking agent is not particularly limited as long as it is capable of hardening the film through a crosslinking reaction, and examples thereof include: (a) an epoxy resin; (b) a melamine compound substituted by at least one substituent selected from methylol groups, alkoxymethyl groups, and acyloxymethyl groups, a guanamine compound substituted by at least one substituent selected from methylol groups, alkoxymethyl groups, and acyloxymethyl groups, a glycoluril compound substituted by at least one substituent selected from methylol groups, alkoxymethyl groups, and acyloxymethyl groups, or a urea compound substituted by at least one substituent selected from methylol groups, alkoxymethyl groups, and acyloxymethyl groups; and (c) a phenol compound substituted by at least one substituent selected from methylol groups, alkoxymethyl groups, and acyloxymethyl groups, a naphthol compound substituted by at least one substituent selected from methylol groups, alkoxymethyl groups, and acyloxymethyl groups, or a hydroxyanthracene compound substituted by at least one substituent selected from methylol groups, alkoxymethyl groups, and acyloxymethyl groups. In particular, polyfunctional epoxy resins are preferable.

With respect to the specifics of the crosslinking agent such as specific examples of the crosslinking agent, paragraphs [0134] to [0147] of JP-A No. 2004-295116 can be referenced.

Surfactant

The colored curable composition according to the invention may contain a surfactant in order to improve the coatability. Examples of the surfactant that can be used in the invention include various surfactants such as a fluorine-containing surfactant, a nonionic surfactant, a cationic surfactant, an anionic surfactant, and a silicone surfactant.

In particular, when the colored curable composition according to the invention contains a fluorine-containing surfactant, the liquid properties (in particular, fluidity) of the composition prepared as a coating liquid are improved, and the uniformity of the coating thickness and the liquid saving property can be improved.

That is, when a colored curable composition including a fluorine-containing surfactant is used as a coating liquid to form a film, the wettability on the surface to be coated is improved due to decrease in the surface tension between the surface to be coated and the coating liquid, and the coatability on the surface to be coated is improved. Therefore, even when a thin film of several micrometers thickness is formed with a small amount of the liquid, a film with uniform thickness may be suitably formed.

The fluorine content in the fluorine-containing surfactant is preferably from 3% by mass to 40% by mass, more preferably from 5% by mass to 30% by mass, and still more preferably from 7% by mass to 25% by mass. When the fluorine content of the fluorine-containing surfactant is within the above range, it is effective in terms of the uniformity of the coating film thickness and the liquid saving, and excellent solubility in the colored curable composition can be achieved.

Examples of the fluorine-containing surfactant include MEGAFAC F171, F172, F173, F176, F177, F141, F142, F143, F144, R30, F437, F475, F479, F482, F554, F780 and F781 (trade names, manufactured by DIC Corporation), FLUORAD FC430, FC431 and FC171 (trade names, manufactured by Sumitomo 3M Limited), SURFLON S-382, SC-101, SC-103, SC-104, SC-105, SC-1068, SC-381, SC-383, S-393 and KH-40 (trade names, manufactured by Asahi Glass Co., Ltd.), and SOLSPERSE 20000 (trade name, manufactured by Lubrizol Japan Limited).

Examples of the nonionic surfactant include glycerol, trimethylolpropane and trimethylolethane, and an ethoxylate or propoxylate product thereof (such as glycerol propoxylate or glycerin ethoxylate); polyoxyethylene lauryl ether, polyoxyethylene stearyl ether, polyoxyethylene oleyl ether, polyoxyethylene octyl phenyl ether, polyoxyethylene nonyl phenyl ether, polyethylene glycol dilaurate, polyethylene glycol distearate, and sorbitan fatty acid esters such as PLURONIC L10, L31, L61, L62, 10R5, 17R2 and 25R2, and TETRONIC 304, 701, 704, 901, 904 and 150R1 (trade names, manufactured by BASF).

Examples of the cationic surfactant include phthalocyanine modified compounds such as EFKA-745 (trade name, manufactured by Morishita & Co., Ltd.), organosiloxane polymers such as KP341 (trade name, manufactured by Shin-Etsu Chemical Co., Ltd.); (meth)acrylic acid based (co)polymers such as POLYFLOW No. 75, No. 90, No. 95 (trade names, manufactured by Kyoeisha Chemical Co., Ltd.); and W001 (trade name, available from Yusho Co., Ltd.).

Examples of the anionic surfactant include W004, W005 and W017 (trade names, available from Yusho Co., Ltd.).

Examples of the silicone surfactant include TORAY SILICONE DC3PA, SH7PA, DC11 PA, SH21PA, SH28PA, SH29PA, SH30PA and SH8400 (trade names, manufactured by Dow Corning Toray Co., Ltd.), TSF-4440, 4300, 4445, 4460 and 4452 (trade names, manufactured by Momentive Performance Materials Inc.), KP341, KF6001, and KF6002 (trade names, manufactured by Shin-Etsu Chemical Co., Ltd.), and BYK307, 323 and 330 (trade names, manufactured by BYK Chemie).

These surfactants may be used singly or in combination of two or more kinds thereof.

The surfactant may be used singly or in combination of two or more kinds thereof.

The additive amount of the surfactant is preferably from 0.001% by mass to 2.0% by mass, more preferably from 0.005% by mass to 1.0% by mass, with respect to the total mass of the colored curable composition.

Polymerization Inhibitor

It is preferable that the colored curable composition according to the invention contains a small amount of a polymerization inhibitor in order to prevent unnecessary heat polymerization of the polymerizable compound during manufacture or storage of the colored curable composition.

Examples of the polymerization inhibitor that can be used in the invention include hydroquinone, p-methoxyphenol, di-t-butyl-p-cresol, pyrogallol, t-butylcatechol, benzoquinone, 4,4′-thiobis(3-methyl-6-t-butylphenol), 2,2′-methylenebis(4-methyl-64-butyl phenol), and N-nitrosophenylhydroxyamine primary cerium salt.

The addition amount of the polymerization inhibitor is preferably from about 0.01% by mass to about 5% by mass, with respect to the total mass of the colored curable composition.

Other Additives

The color curable composition may include, as necessary, various additives such as fillers, polymer compounds other than those described above, nonionic surfactants, cationic surfactants, anionic surfactants, adhesion improvers, antioxidants, UV absorbers, and aggregation inhibitors. Examples of such additives include those described in paragraphs [0155] to [0156] of JP-A No. 2004-295116.

The color curable composition according to the invention may include an additive selected from the sensitizers and light stabilizers described in paragraph [0078] of JP-A No. 2004-295116 and thermal polymerization inhibitors described in paragraph of JP-A No. 2004-295116.

An organic carboxylic acid, preferably a low-molecular organic carboxylic acid having a molecular weight of 1,000 or less, is preferably added to the composition, with a view to increasing the alkali-solubility of uncured portions and further improving the developability of the color curable composition.

Specific examples thereof include aliphatic monocarboxylic acids such as formic acid, acetic acid, propionic acid, butyric acid, valeric acid, pivalic acid, caproic acid, diethylacetic acid, enanthic acid, and caprylic acid; aliphatic dicarboxylic acids such as oxalic acid, malonic acid, succinic acid, glutaric acid, adipic acid, pimelic acid, suberic acid, azelaic acid, sebacic acid, brassylic acid, methylmalonic acid, ethylmalonic acid, dimethylmalonic acid, methylsuccinic acid, tetramethylsuccinic acid, and citraconic acid; aliphatic tricarboxylic acids such as tricarballylic acid, aconitic acid, and camphoronic acid; aromatic monocarboxylic acids such as benzoic acid, toluic acid, cuminic acid, hemellitic acid, and mesitylenic acid; aromatic polycarboxylic acids such as phthalic acid, isophthalic acid, terephthalic acid, trimellitic acid, trimesic acid, mellophanic acid, and pyromellitic acid; and other carboxylic acids such as phenylacetic acid, hydroatropic acid, hydrocinnamic acid, mandelic acid, phenylsuccinic acid, atropic acid, cinnamic acid, methyl cinnamate, benzyl cinnamate, cinnamylideneacetic acid, coumaric acid, and umbellic acid.

The color curable composition according to the invention has excellent storage stability and is capable of forming a color cured film having excellent light fastness. Therefore, the color curable composition according to the invention can be suitably used for forming color pixels of color filters for use in liquid crystal displays (LCDs) and solid-state image pick-up devices (such as CCDs and CMOSs), and for producing print inks, inkjet inks, and paints. The color curable composition according to the invention is particularly suitable for forming color pixels of solid-state image pick-up devices such as CCDs and CMOSs.

<Color Filter and Method of Producing the Same>

Next, a method of producing a color filter using the color curable composition according to the invention (the method of producing a color filter according to the invention) is described.

The method of producing a color filter according to the invention includes: a process (A) of forming a color curable composition layer on a support by applying the color curable composition according to the invention; and a process (B) of forming a color pattern by exposing the color curable composition layer formed by the process (A) to light through a mask and thereafter developing the color curable composition layer.

The method of producing a color filter according to the invention preferably further includes a process (C) of irradiating the color pattern formed by the process (B), with UV light, and a process (D) of subjecting the color pattern that has been irradiated with UV light in the process (C) to a heating treatment.

In the following, the method of producing a color filter according to the invention is described more specifically.

Process (A)

In the method of producing a color filter according to the invention, the color curable composition according to the invention is applied onto a support using an application method, such as spin coating, cast coating, roll coating or inkjet coating, to form a color curable composition layer. Then the color curable composition layer may, as necessary, be subjected to pre-curing (pre-baking), and may be dried.

Examples of the support for use in the method of producing a color filter according to the invention include: alkali-free glass, soda glass, borosilicate glass (PYREX (registered trademark) glass), quartz glass, and materials obtained by attaching a transparent conductive film to these glasses, which are used in liquid crystal display devices and the like; photoelectric conversion device substrates and silicon substrates, which are used in solid-state image pick-up devices such as CCD and CMOS. In some cases, black stripes that separate the respective pixels are formed on the substrate. On these substrates, an undercoat layer may be formed, as necessary, in order to improve adhesion to an upper layer, prevent diffusion of substances, or flatten the surface.

When a color curable composition is applied onto the support by spin coating, in order to reduce the amount of liquid to be dropwise applied, an appropriate organic solvent may be dropwise deposited on the support and the support may be rotated, prior to the dropwise deposition of the color curable composition. This treatment improves affinity of the color curable composition for the support.

Regarding the conditions for pre-baking, pre-baking may be performed at a temperature of from 70° C. to 130° C. for a period of from 0.5 minutes to 15 minutes using, for example, a hot plate or an oven.

The thickness of the color curable composition layer formed from the color curable composition may be appropriately selected in accordance with the purpose, and, in general, the thickness of the color curable composition layer is preferably from 0.2 μm to 5.0 μm, more preferably from 0.3 μm to 2.5 μm, and most preferably from 0.3 μm to 1.5 μm. The thickness of the color curable composition layer as described herein refers to thickness after pre-baking.

Process (B)

Subsequently, the color curable composition layer formed on the support is exposed to light through a mask, in the method of producing a color filter according to the invention.

The light or radiation that can be applied to the exposure is preferably g-line, h-line, i-line, KrF light, or ArF light, and i-line is particularly preferable. When i-line is used as an irradiation light, i-line is preferably irradiated at an exposure amount of from 100 mJ/cm² to 10,000 mJ/cm².

The color curable composition layer that has been exposed to light may be heated, prior to a subsequent development process, at a temperature of from 70° C. to 180° C. for a period of from 0.5 minutes to 15 minutes using, for example, a hot plate or an oven.

The exposure to light may be conducted in a chamber under nitrogen gas glow, in order to suppress discoloration of a colorant in the color curable composition layer caused by oxidation.

Thereafter, the color curable composition layer after the exposure to light may be developed with a developer, as a result of which a negative or positive color pattern (resist pattern) can be formed.

The developer may be selected from various combination of organic solvents, and aqueous alkaline solutions, provided that the developer dissolves uncured portions (unexposed portions) of the color curable composition layer but does not dissolve cured portions (exposed portions) of the color curable composition layer.

Examples of the aqueous alkaline solutions include an aqueous solution, in which a compound such as sodium hydrate, potassium hydrate, sodium carbonate, sodium hydrogen carbonate, sodium silicate, sodium metasilicate, aqueous ammonia, ethylamine, diethylamine, dimethylethanolamine, tetramethylammonium hydroxide, tetraethylammonium hydroxide, choline, pyrrole, piperidine or 1,8-diazabicyclo-[5.4.0]-7-undecene, is prepared such that the aqueous solution has an alkali concentration of from pH 11 to pH 13, and more preferably from pH 11.5 to pH 12.5.

For example, an aqueous alkaline solution that contains tetramethylammonium hydroxide at a concentration of from 0.001% by mass to 10% by mass, preferably from 0.01% by mass to 5% by mass, may be used as the developer.

The development time is preferably from 30 seconds to 300 seconds, and more preferably from 30 seconds to 120 seconds. The development temperature is preferably from 20° C. to 40° C., more preferably 23° C.

The development may be performed by a paddle method, a shower method, a spray method, or the like.

After the color curable composition layer is developed by using an aqueous alkaline solution, it is preferable to perform washing with water. The washing method may be appropriately selected in accordance with the purpose. For example, a rinse treatment whereby pure water is showered from a discharge nozzle onto the support (e.g., a silicon wafer substrate) that is being rotated at a rotation number of from 10 rpm to 500 rpm such that the pure water is supplied onto the support from above the rotation center of the support.

Thereafter, in the method of producing a color filter according to the invention, the color pattern formed by the development may be, if necessary, subjected to post-heating and/or post-exposure to light, thereby promoting the curing of the color pattern.

Process (C)

In the method of producing a color filter according to the invention, the color pattern (pixels) formed form the color curable composition may be subjected to post-exposure by irradiation with UV light, thereby effectively suppressing color transfer to adjacent pixels or to an upper or lower layer in the layered structure. The color transfer can be reduced by performing post-exposure by irradiation with UV light as described below.

(Post-Exposure to Light by Irradiation with UV Light)

In the post-exposure by irradiation with UV light, the color pattern after subjected to a development treatment as described above is preferably irradiated with UV light at an irradiation amount [mJ/cm²] that is at least 10 times greater than the exposure amount [mJ/cm²] employed in the exposure treatment conducted before the development.

When the color pattern after the development is irradiated with UV light for a certain time during a period between the development treatment and the heating treatment of the below-described process (D), color transfer is effectively prevented when heated afterwards, and light fastness is improved.

The light source for irradiating UV light may be, for example, a ultrahigh pressure mercury lamp, a high pressure mercury lamp, a low pressure mercury lamp, or a DEEP UV lamp. In particular, it is preferable that the light source emits UV light that includes a light component having a wavelength of 275 nm or less and that the irradiance of light components having a wavelength of 275 nm or less is 5% or higher relative to the integrated irradiance over the entire wavelength range of the UV light. When the proportion of the irradiance of light components having a wavelength of 275 nm or less in the UV light is 5% or higher, color transfer between adjacent pixels or color transfer to an upper or lower layer is further suppressed, and light fastness is further improved.

From this viewpoint, the post-exposure to light by irradiation with UV light is preferably conducted using a light source that is different from the light source (e.g., an emission line such as i-line) used for the exposure to light conducted in the process (B), and, specifically, the post-exposure is preferably conducted using, for example, a high pressure mercury lamp or a low pressure mercury lamp. For reasons similar to the above, the irradiance of light components having a wavelength of 275 nm or less is preferably 7% or higher relative to the integrated irradiance over the entire wavelength range of the UV light. The upper limit of the proportion of the irradiance of light components having a wavelength of 275 nm or less is preferably 25% or lower.

The integrated irradiance as used herein refers to the total sum of the irradiances of light components having different wavelengths contained in the irradiated light. When a irradiance curve is drawn on a graph in which the vertical axis represents spectral irradiance (the radiation energy that passes a unit area within a unit time [mW/m²] at each spectral wavelength) and the horizontal axis represents the wavelength [nm] of light component, the integrated irradiance is obtained as the total area of irradiance over the entire wavelength range of the irradiated light.

The irradiation of UV light may be performed preferably at an irradiance [mJ/cm²] that is at least 10 times greater than the exposure amount of the light exposure conducted in the process (B). When the irradiance in the process (C) is at least 10 times greater than the exposure amount of the light exposure conducted in the process (B), color transfer between adjacent pixels or color transfer between upper and lower layers may be prevented, and light fastness may be improved.

The irradiance of UV light is more preferably from 12 times to 200 times greater than the exposure amount of the light exposure conducted in the process (B), and is still more preferably from 15 times to 100 times greater than the exposure amount of the light exposure conducted in the process (B).

The integrated irradiance of the irradiated UV light is preferably 200 mW/cm² or higher. When the integrated irradiance is 200 mW/cm² or higher, color transfer between adjacent pixel and color transfer to an upper or lower layer are more effectively suppressed, and light fastness is more effectively enhanced. The integrated irradiance is more preferably from 250 mW/cm² to 2,000 mW/cm², and more preferably from 300 mW/cm² to 1,000 mW/cm².

Process (D)

It is preferable to subject the color pattern that has been subjected to post-exposure by irradiation with UV light as described above, to a heating treatment. By heating (post-baking) the color pattern formed, the color pattern can be further cured.

The heating treatment can be performed using, for example a hot plate, a heater which may be selected from various types of heater, or an oven.

The temperature of the heating treatment is preferably from 100° C. to 300° C., and more preferably from 150° C. to 250° C. The heating time is preferably from 30 seconds to 30,000 seconds, and more preferably from 60 seconds to 1,000 seconds.

In the method of producing a color filter according to the invention, a post-exposure by g-line, h-line, i-line, KrF, ArF, electron beams, X rays, or the like may be conducted instead of the post-exposure by irradiation with UV light performed in the process (C) described above.

When the post-exposure by such a means is conducted, the irradiation time may be from 10 seconds to 180 seconds, preferably from 20 seconds to 120 seconds, and still more preferably from 30 seconds to 60 seconds.

In the method of producing a color filter according to the invention, it is permissible that the post-exposure by irradiation with UV light as in the process (C) is not performed, and only the post-exposure as in the process (D) is performed.

Further, any one of the post-exposure or the post-heating (post-baking) may be performed first. It is preferable that the post-exposure is performed prior to the post-baking. This is because the post-exposure promotes curing, and thus prevents deformation due to thermal sagging (rounding of a rectangular pattern) or footing (returning of a lower layer portion of a pattern to fluid state) of the color pattern which is otherwise observed during the post-heating process.

The color pattern thus obtained forms pixels of a color filter.

When a color filter having pixels of plural hues, the process (A), the process (B), and, optionally, at least one of the process (C) or the process (D) may be repeated in accordance with the number of desired hues.

The process (C) and/or the process (D) may be conducted every time the formation, exposure to light, and development of the color curable composition layer for one color are completed (i.e., conducted for each color), or, alternatively, may be conducted only once after the formation, exposure to light, and development of the color curable composition layers for all of the desired number of colors are completed.

A color filter obtained using the method of producing a color filter according to the invention (a color filter according to the invention) has excellent light fastness since the color curable composition according to the invention is used.

Therefore, the color filter according to the invention can be used in liquid crystal displays, solid-state image pick-up devices such as CCD image sensors and CMOS image sensors, and camera systems using the solid-state image pick-up devices. The color filter according to the invention is suitable for solid-state image pick-up device applications in which color patterns having minute sizes are formed with small thicknesses and in which excellent rectangular section profiles are required, and is particularly suitable for applications such as high-resolution (such as a resolution over million pixels) CCD devices and CMOS.

<Solid-state Image Pick-Up Device>

The solid-state image pick-up device according to the invention has the color filter according to the invention. The color filter according to the invention has high light fastness, and a solid-state image pick-up device having the color filter realizes excellent color reproduction.

The configuration of the solid-state image pick-up device is not particularly limited as long as the configuration is equipped with the color filter according to the invention and is capable of functioning as a solid-state image pick-up device. The configuration of the solid-state image pick-up device is, for example, the following configuration.

Specifically, in a configuration, plural photodiodes and transfer electrodes (formed from, for example, polysilicon), which form light-receiving areas of a CCD image sensor (solid-state image pick-up device), are provided on a support, and the color filter according to the invention is provided thereon, and then microlenses are disposed thereon.

A camera system equipped with the color filter according to the invention preferably has a camera lens or IR cut film that has a dichroic-coated cover glass, microlens, or the like from the viewpoint of discoloration of colorant by light, and the optical characteristics of the material of the dichroic coating is preferably such that the dichroic coating absorbs all or part of UV light component having a wavelength of 400 nm or less. The structure of the camera system is preferably such that the oxygen permeability into the color filter is decreased, with a view to preventing discoloration of colorant by oxidation. For example, it is preferable that all or part of the camera system is enclosed in a nitrogen gas.

<Liquid Crystal Display Device>

The color filter according to the invention has excellent hue, and colored pixels with reduced defects, detachment and crinkle are formed thereon. Therefore, the color filter according to the invention can be suitably used for liquid crystal display devices.

The liquid crystal display device having such a color filter can display high quality images.

Definition and explanation of display devices are given, for example, in “Electronic Display Device” (Akio Sasaki, Kogyo Chosakai Publishing Co., Ltd., 1990), “Display Device” (Sumiaki Ibuki, Sangyo Tosho Publishing Co., Ltd., 1989) and the like. Liquid crystal display devices are described, for example, in “Next Generation Liquid Crystal Display Techniques” (Tatsuo Uchida, Kogyo Chosakai Publishing Co., Ltd., 1994). Liquid crystal display devices to which the color filter according to the invention may be applied are not particularly limited, and the color filter according to the invention may be used for various liquid crystal display devices such as those described, for example, in “Next Generation Liquid Crystal Display Techniques”.

In particular, the color filter according to the invention can suitably be used in a color TFT liquid crystal display device. Details of color TFT liquid crystal display devices are described, for example, in “Color TFT Liquid Crystal Display” (Kyoritsu Shuppan Co., Ltd., 1996). Further, the color filter according to the invention may be applied to a liquid crystal display device with a wider view angle such as an in-plane switching (IPS) system or a multi-domain vertical alignment (MVA) system, or STN, TN, VA, OCS, FFS, R-OCB and the like.

The color filter according to the invention may also be applied to a COA (Color-filter On Array) system, which has high brightness and high definition. In the COA type liquid crystal display device, the color filter layer should satisfy the normal requirements mentioned above, and further requirements for an interlayer dielectric film such as low dielectric constant and resistance to a removal liquid. In the color filter according to the invention, since exposure is conducted using a UV light laser and the pixel hue and film thickness defined in the present invention are selected, the transmittance of the exposing light, which is a UV light laser, can be improved. As a result, the curability of the colored pixels can be improved, and pixels with reduced defects, detachment and crinkle can be obtained. Therefore, the color filter according to the invention is suitably used in liquid crystal display devices employing the COA system, since resistance to a removal liquid can be improved in a color layer formed directly or indirectly on a TFT substrate. In order to satisfy the requirement of low dielectric constant, a resin coating may be provided on the color filter layer.

In the colored layer formed according to the COA system, in order to electrically connect the ITO electrode disposed on the colored layer and the terminal of the driving substrate disposed below the colored layer, an electrically-conducting path such as a rectangular through hole having a side length of about 1 μm to 15 μm or a U-shaped depressed area should be formed, in which the size (that is, the side length) of the electrically-conducting path is preferably 5 μm or less. According to the present invention, an electrically-conducting path having a size of 5 μm or less can be formed.

These image display systems are described, for example, on page 43 of “EL, PDP, LCD Display—Trends in Techniques and Markets” (Research Study Division of Toray Research Center, Inc., 2001) and the like.

The liquid crystal display device according to the invention includes not only the color filter according to the invention but also various members such as an electrode substrate, a polarization film, a phase difference film, a back light, a spacer, and a view angle compensation film. The color filter according to the invention may be applied to a liquid crystal display device including these various known members.

These members are described, for example, in “'94 Market for Liquid Crystal Display Related Materials and Chemicals” (Kentaro Shima, CMC Publishing CO., LTD., 1994) and “2003 Current State and Outlook for Liquid Crystal Related Markets” (Ryokichi Omote, Fuji Chimera Research Institute, Inc., 2003).

Back lights are described, for example, in SID meeting Digest 1380 (2005) (A. Konno et. al) and Monthly Display, 2005 December, pages 18-24 (Hiroyasu Shima) and pages 25-30 (Takaaki Yagi).

When the color filter according to the invention is used in a liquid crystal display device, high-contrast display may be achieved in combination with a conventionally known three-wavelength cold-cathode tube. Furthermore, by using red, green and blue LED light sources (RGB-LED) as a back light, a liquid crystal display device having high brightness, high color purity, and good color reproducibility may be provided.

### EXAMPLES

The present invention is described more specifically below by reference to examples. However, the scope of the invention is not limited to the examples, and encompasses other embodiments as long as the gist of the invention is retained. Hereinafter, “part” and “%” are both based on mass, unless otherwise indicated.

### Example 1

### (1) Preparation of Dye Solution

0.183 parts of a specific complex (Exemplary Compound Ia-3 shown above) are added to 1.133 parts of cyclohexanone, and the resultant mixture was agitated at normal temperature for 60 minutes using a mix rotor (manufactured by AS ONE Corporation), as a result of which a dye solution was obtained.

### (2) Preparation of Pigment Dispersion Liquid

First, Pigment Blue 15:6 (HELIOGEN L6700F (tradename) manufactured by BASF Corporation) was fined as follows.

Specifically, ingredients of the following composition were placed in a double-arm kneader, and kneaded at 80° C. for 30 hours. Thereafter, the mixture obtained was added into 100 parts of a 1% hydrochloric acid aqueous solution having a temperature of 80° C., and agitated for 1 hour. Thereafter, the resultant was filtered, washed with hot water, dried, and pulverized, as a result of which a fine pigment of Pigment Blue 15:6 was obtained.

| | |
|---|---|
| Pigment Blue 15:6 | 40 parts |
| Crushed sodium chloride | 400 parts |
| Diethyleneglycol | 80 parts |

Then, a mixture having the following composition was prepared using the obtained fine pigment, and the mixture was dispersed for 7 hours using a DISPERMAT (beads: zirconia beads having a diameter of 0.5 mm) manufactured by VMA-GETZMANN GMBH, as a result of which a pigment dispersion liquid was obtained. The obtained pigment dispersion liquid had a solids concentration of 17.70% and a pigment concentration of 11.80%.

| | |
|---|---|
| Pigment Blue 15:6 | 8.26 parts |
| A 30% solution of a dispersant (the resin prepared in | 13.77 parts |
| Synthesis Method 2 described in JP-A No. 2009-109750) | |
| in propyleneglycol methyl ether acetate | |
| Propyleneglycol monomethyl ether acetate as a solvent | 47.97 parts |

### (3) Preparation of Color Curable Composition (Method-A)

Ingredients, including the dye solution and the pigment dispersion liquid obtained, were mixed at the following compositional ratio, as a result of which a color curable composition was obtained.

(Composition of Color Curable Composition)

| | |
|---|---|
| The dye solution obtained in (1) above | 1.316 parts |
| The pigment dispersion liquid obtained in (2) above | 2.418 parts |
| Copolymer of benzyl methacrylate/methacrylic acid | 1.009 parts |
| (in a molar ratio of 70/30, the copolymer having a | |
| weight average molecular weight of 30,000 and being in the | |
| state of 20% solution in cyclohexanone) | |
| Fluorosurfactant (F-475 (tradename) manufactured by | 0.125 parts |
| DIC Corporation) | |
| Dipentaerythritol hexaacrylate (DPHA (tradename) | 2.0 parts |
| manufactured by NIHON KAYAKU Co., Ltd.) | |
| Oxime photopolymerization initiator (compound having the | 0.087 parts |
| following structure) | |
| Surfactant (glycerol propoxylate in the form of a 1% solution in | 0.048 parts |
| cyclohexanone) | |

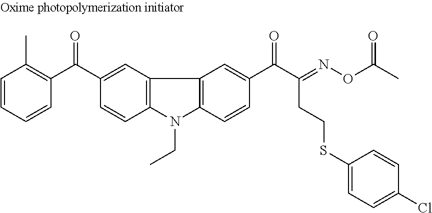

### Comparative Example 1

### (4) Preparation of Color Curable Composition (Method-B)

Ingredients described below were sequentially mixed, and the resultant mixture was stirred for 1,200 minutes using a stirrer.

| | |
|---|---|
| Cyclohexanone | 1.133 parts |
| Benzyl methacrylate/methacrylic acid copolymer (in a | 1.009 parts |
| molar ratio of 70:30, the copolymer having a weight | |
| average molecular weight of 30,000 and being in the | |
| state of a 20% solution in cyclohexanone) | |
| Fluorosurfactant (F-475 (tradename) manufactured | 0.125 parts |
| by DIC Corporation) | |
| Dipentaerythritol hexaacrylate (DPHA (tradename) | 2.0 parts |
| manufactured by NIHON KAYAKU Co., Ltd.) | |
| Oxime photopolymerization initiator (compound | 0.087 parts |
| having the above structure) | |
| Specific complex (Exemplary Compound Ia-3 shown | 0.183 parts |
| above) | |
| The pigment dispersion liquid obtained in (2) above | 2.418 parts |
| Surfactant (glycerol propoxylate in the form of a 1% | 0.048 parts |
| solution in cyclohexanone) | |

### (5) Preparation of Silicon Wafer Having Undercoat Layer

The ingredients of the following resist composition were mixed and dissolved, thereby preparing a resist solution for forming an undercoat layer.

<Resist Composition>

| | |
|---|---|
| Binder polymer (benzyl methacrylate/methacrylic acid/2- | 30.51 parts |
| hydroxyethyl methacrylate copolymer in a molar ratio of | |
| 60/22/18, the copolymer being in the state of a 40% | |
| solution in PGMEA) | |
| Polymerizable compound (dipentaerythritol hexaacrylate) | 12.20 parts |
| Polymerization inhibitor (p-methoxyphenol) | 0.0061 parts |
| Fluorosurfactant (F-475 (tradename) manufactured by | 0.83 parts |
| DIC Corporation) | |
| Photopolymerization initiator (TAZ-107 (tradename) | 0.586 parts |
| manufactured by Midori Kagaku Co., Ltd., which is a | |
| trihalomethyl triazine photopolymerization initiator) | |
| Solvent (PGMEA) | 19.20 parts |
| Solvent (ethyl lactate) | 36.67 parts |

A 6-inch silicon wafer was subjected to a heating treatment at 200° C. for 30 minutes in an oven. Subsequently, the above resist solution was applied onto the silicon wafer such that dry thickness became 2 μm, followed by drying by heating in an oven at 220° C. for 1 hour to form an undercoat layer, as a result of which a silicon wafer substrate having an undercoat layer was obtained.

### (6) Production of Color Filter for Solid-State Image Pick-Up Device

The color curable composition of Example 1 obtained above was applied onto the above silicon wafer having an undercoat layer by spin coating method, and then heated on a hot plate at 120° C. for 2 minutes to form a color curable composition layer.

Then, the obtained color curable composition layer was exposed to light through a photomask having a 1 μm×1 μm pattern at an exposure amount of 1,000 mJ/cm² using an i-line stepper. The color curable composition layer after the exposure to light was subjected to paddle development at 25° C. for 40 seconds using a 0.3% aqueous solution of tetramethylammonium hydroxide. Thereafter, rinsing with a spin shower was conducted, and washing with pure water was further performed, as a result of which a color filter for a solid-state image pick-up device was obtained.

### Examples 2 to 8 and Comparative Examples 2 to 8

Color curable compositions of Examples 2 to 8 were obtained in the same manner as the above method A (for preparation of a color curable composition), except that the type of the dye and the type and compositional ratio of the organic solvent were changed as shown in Table 1 and that the amount of the solvent was changed to give the solids contents shown in Table 1. Color curable compositions of Comparative Examples 2 to 8 were obtained in the same manner as the above method B (for preparation of a color curable composition), except that the type of the dye and the type and compositional ratio of the organic solvent were changed as shown in Table 1 and that the amount of solvent was changed to give the solids contents shown in Table 1. As described above, the solids contents of the color curable compositions were varied since the amounts of organic solvents were varied. The dispersion stability was evaluated by the following method, using each of the obtained color curable compositions.

In the column for organic solvent in Table 1 below and the description of organic solvent in (5) resist composition above, the following abbreviations are used.
PGMEA: propyleneglycol monomethyl ether acetate
PGME: propyleneglycol monomethyl ether
EL: ethyl lactate

Further, in Table 1, the numbers in parentheses indicate compositional ratios (by mass) when two organic solvents are used, and (100) indicates that a single organic solvent is used.

Evaluation of Dispersion Stability

The evaluation of dispersion stability was conducted by measuring viscosity. Each of the obtained color curable compositions was measured with respect to viscosity η1 of the color curable composition directly after the preparation thereof and viscosity η2 of the color curable composition when the color curable composition was left to stand at room temperature for one week after the preparation thereof, using an E-type viscometer (RE-810 (tradename) manufactured by TOKI SANGYO CO., LTD.). From the measured values, the degree of increase in viscosity was evaluated in terms of Δη defined by the following formula. The evaluation results are shown in Table 1. Here, a smaller viscosity increase indicates a more favorable dispersibility and dispersion stability.

Δη=(η2−η1)η1×100(%) Formula:

Evaluation Criteria

### A: Δη<30(%)

### B: 30(%)≦Δη<100(%)

### C: 100(%)≦Δη

TABLE 1

| | | | | Preparation | Results of |
|---|---|---|---|---|---|
| | | | | Method of | Evaluation of |
| | | | Solids | Color Curable | Dispersion |
| | Dye | Solvent | Content | Composition | Stability |
| Example 1 | Ia-3 | Cyclohexanone | 0.218 | Method-A | A |
| | | (100) | | | |
| Example 2 | Ia-5 | PGMEA (100) | 0.164 | Method-A | A |
| Example 3 | Ia-A | Cyclohexanone/ | 0.193 | Method-A | A |
| | | PGME (50/50) | | | |
| Example 4 | II-7 | PGMEA/EL | 0.132 | Method-A | A |
| | | (50/50) | | | |
| Example 5 | III-5 | Cyclohexanone/ | 0.148 | Method-A | A |
| | | PGMEA | | | |
| | | (20/80) | | | |
| Example 6 | III-A | PGMEA (100) | 0.183 | Method-A | A |
| Example 7 | III-60 | PGMEA (100) | 0.168 | Method-A | A |
| Example 8 | III-A/III-60 | PGMEA (100) | 0.155 | Method-A | A |
| | (50/50) | | | | |
| Comparative | Ia-3 | Cyclohexanone | 0.218 | Method-B | B |
| Example 1 | | (100) | | | |
| Comparative | Ia-5 | PGMEA (100) | 0.164 | Method-B | B |
| Example 2 | | | | | |
| Comparative | Ia-A | Cyclohexanone/ | 0.193 | Method-B | C |
| Example 3 | | PGME (50/50) | | | |
| Comparative | II-7 | PGMEA/EL | 0.132 | Method-B | C |
| Example 4 | | (50/50) | | | |
| Comparative | III-5 | Cyclohexanone/ | 0.148 | Method-B | C |
| Example 5 | | PGMEA | | | |
| | | (20/80) | | | |
| Comparative | III-A | PGMEA (100) | 0.183 | Method-B | B |
| Example 6 | | | | | |
| Comparative | III-60 | PGMEA (100) | 0.168 | Method-B | B |
| Example 7 | | | | | |
| Comparative | III-A/III-60 | PGMEA (100) | 0.155 | Method-B | B |
| Example 8 | (50/50) | | | | |

From the results shown in Table 1, the following observation can be made.

The color curable compositions of Examples 1 to 8, which were prepared using the method-A according to the invention, exhibited excellent dispersion stability. In contrast, the color curable compositions of Comparative Examples 1 to 8, which were prepared using the method-B, in which a dye is directly mixed with a pigment dispersion liquid rather than via preparation of a dye solution, exhibited inferior dispersion stability.

According to the invention, a method of preparing a color curable composition having excellent dispersion properties and excellent dispersion stability is provided. The invention also provides a color curable composition obtainable by the method of preparing a color curable composition. The invention further provides a method of producing a color filter which has high color purity and in which occurrence of color unevenness is suppressed, and a color filter obtainable by the method. The invention still further provides a solid-state image pick-up device having high resolution.

All publications, patent applications, and technical standards mentioned in this specification are herein incorporated by reference to the same extent as if each individual publication, patent application, or technical standard was specifically and individually indicated to be incorporated by reference.

1. A method of preparing a color curable composition, comprising:
preparing a dye solution by dissolving at least a dye in an organic solvent;
preparing a pigment dispersion liquid by dispersing at least a pigment using a dispersant; and
mixing the dye solution and the pigment dispersion liquid.

2. The method of preparing a color curable composition according to claim 1, wherein an amount of solids contained in the color curable composition is from 13% by mass to 20% by mass relative to the entire color curable composition.

3. The method of preparing a color curable composition according to claim 1, wherein an amount of pigments contained in the color curable composition is from 10% by mass to 60% by mass relative to an amount of solids contained in the color curable composition, and an amount of dyes contained in the color curable composition is from 10% by mass to 60% by mass relative to the amount of solids contained in the color curable composition.

4. The method of preparing a color curable composition according to claim 1, wherein an amount of dyes contained in the color curable composition is from 20% by mass to 500% by mass relative to an amount of pigments contained in the color curable composition.

5. The method of preparing a color curable composition according to claim 1, wherein the organic solvent contained in the dye solution is at least one selected from the group consisting of cyclohexanone, propyleneglycol monomethyl ether acetate, propyleneglycol monomethyl ether, and ethyl lactate.

6. The method of preparing a color curable composition according to claim 1, wherein the pigment includes a phthalocyanine pigment, and the dye is a complex in which a compound represented by the following Formula (I) coordinates to a metal atom or metal compound: 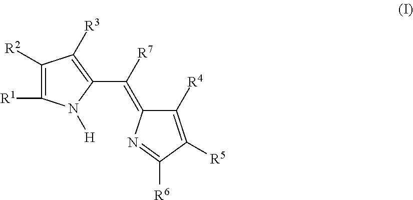
wherein, in Formula (I), R¹ to R⁶ each independently represent a hydrogen atom or a substituent, and R⁷ represents a hydrogen atom, a halogen atom, an alkyl group, an aryl group, or a heterocyclic group.

7. A color curable composition obtainable by the method of preparing a color curable composition according to claim 1.

8. The color curable composition according to claim 7, further comprising a polymerizable compound and a polymerization initiator.

9. A method of producing a color filter, comprising:
fixating a color curable composition layer by applying the color curable composition according to claim 7 onto a support; and
forming a color pattern by exposing the color curable composition layer to light through a mask and thereafter developing the color curable composition layer.

10. A color filter obtainable by the method of producing a color filter according to claim 9.

11. A solid-state image pick-up device comprising the color filter according to claim 10.
